(19) United States
(12) Patent Application Publication
(10) Pub. No.: US 2026/0020437 A1
(43) Pub. Date: Jan. 15, 2026

(54) DISPLAY PANEL AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Qing DAI, Beijing (CN); Cheng XU, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/994,449

(22) PCT Filed: May 15, 2023
(86) PCT No.: PCT/CN2023/094211

§ 371 Date: Jan. 14, 2025

(51) Int. Cl. H10K 59/121; H10K 59/122; H10K 59/131; H10K 59/35; H10K 59/88

(52) U.S. Cl. CPC H10K 59/1213; H10K 59/1216; H10K 59/122; H10K 59/131; H10K 59/35; H10K 59/88

(57) ABSTRACT

A display panel and a display device, including: a base substrate and sub-pixels disposed thereon; a pixel circuit layer and a planarization layer, disposed on the base substrate; and a pixel defining layer on the planarization layer and including first, second and third sub-pixel openings. The pixel circuit layer includes a first conductive layer including first circuit patterns of the sub-pixels, and an orthographic projection of the first circuit patterns on the base substrate overlaps with an orthographic projection of at least one of the first, second and third sub-pixel openings on the base substrate; and a ratio of an overlapping area of the first circuit patterns with the third sub-pixel opening to an area of the third sub-pixel opening is smaller than a ratio of an overlapping area of the first circuit patterns with the first sub-pixel opening to an area of the first sub-pixel opening.

### TECHNICAL FIELD Embodiments of the present disclosure relate to a display panel and a display device.

### BACKGROUND

Among various display devices, organic light emitting diode (OLED) display panel is widely used in the display field because of its advantages of self-luminescence, wide viewing angle and fast response. OLED display panel includes a plurality of sub-pixels, and usually includes a pixel circuit layer, a light-emitting device layer and a planarization layer located between the pixel circuit layer and the light-emitting device layer, and the light-emitting device requires high surface flatness of the planarization layer. If the light-emitting device is formed on an uneven surface, it may lead to non-uniform light emission of the light-emitting device, thus affecting the display quality of the display panel.

### SUMMARY

At least one embodiment of the present disclosure provides a display panel, including: a base substrate; a plurality of sub-pixels, disposed on the base substrate, wherein each sub-pixel includes a light-emitting device and a sub-pixel circuit for driving the light-emitting device to emit light, and the plurality of sub-pixels include a first sub-pixel, a second sub-pixel and a third sub-pixel for displaying different colors; a pixel circuit layer, including sub-pixel circuits of the plurality of sub-pixels and including a first sub-pixel circuit, a second sub-pixel circuit and a third sub-pixel circuit for respectively driving light-emitting devices of the first sub-pixel, the second sub-pixel and the third sub-pixel to emit light; a planarization layer, disposed on a side of the pixel circuit layer away from the base substrate; and a pixel defining layer, disposed on a side of the planarization layer away from the pixel circuit layer, wherein the pixel defining layer has a plurality of sub-pixel openings each configured to define a light-emitting region of a corresponding sub-pixel, and at least a part of the light-emitting device of each sub-pixel is located in a corresponding sub-pixel opening, wherein the plurality of sub-pixel openings include a first sub-pixel opening, a second sub-pixel opening and a third sub-pixel opening corresponding to the first sub-pixel, the second sub-pixel and the third sub-pixel, respectively; wherein the pixel circuit layer includes a first conductive layer including a plurality of first circuit patterns of the plurality of sub-pixels, and an orthographic projection of the plurality of first circuit patterns on the base substrate overlaps with an orthographic projection of at least one of the first sub-pixel opening, the second sub-pixel opening and the third sub-pixel opening on the base substrate; and a ratio of an overlapping area of the plurality of first circuit patterns with the third sub-pixel opening to an area of the third sub-pixel opening is smaller than a ratio of an overlapping area of the plurality of first circuit patterns with the first sub-pixel opening to an area of the first sub-pixel opening or a ratio of an overlapping area of the plurality of first circuit patterns with the second sub-pixel opening to an area of the second sub-pixel opening.

In the display panel provided by at least one embodiment of the present disclosure, an orthographic projection of at least a part of the third sub-pixel circuit on the base substrate is located outside an orthographic projection of the third sub-pixel opening on the base substrate, and overlaps with an orthographic projection of the first sub-pixel opening or the second sub-pixel opening on the base substrate.

In the display panel provided by at least one embodiment of the present disclosure, each sub-pixel circuit includes one or more thin film transistor and one or more capacitor; each thin film transistor includes a gate electrode, a source/drain electrode and an active layer; each capacitor includes electrode plates opposite to each other; the pixel circuit layer further includes a plurality of wires connected to a plurality of thin film transistors and capacitors of the plurality of sub-pixel circuits, and the plurality of wires include at least one of a group consisting of a gate signal line, a data signal line, a common electrode line, a detection signal line, a power supply voltage line and an auxiliary connection line; and the pixel circuit layer includes a plurality of layers of circuit patterns, and the plurality of first circuit patterns of the first conductive layer include gate electrodes or source/drain electrodes of the plurality of thin film transistors, and further include at least one of a group consisting of the electrode plates of the capacitors and the plurality of wires.

In the display panel provided by at least one embodiment of the present disclosure, the pixel circuit layer includes a plurality of pattern layers each including a plurality of patterns, and the first conductive layer is an uppermost pattern layer among the plurality of pattern layers which is closest to the light-emitting device in a direction perpendicular to a main surface of the base substrate, or the first conductive layer is located on a side, away from the light-emitting device, of the uppermost pattern layer among the plurality of pattern layers.

In the display panel provided by at least one embodiment of the present disclosure, the pixel circuit layer further includes a second conductive layer and an active material layer, and each sub-pixel circuit includes a first circuit pattern located at the first conductive layer, a second circuit pattern located at the second conductive layer and an active pattern located at the active material layer; and the first conductive layer is a layer where a gate electrode of a thin film transistor of the sub-pixel circuit is located, the second conductive layer is a layer where a source/drain electrode of the thin film transistor of the sub-pixel circuit is located, and the active material layer is a layer where an active layer of the thin film transistor of the sub-pixel circuit is located.

In the display panel provided by at least one embodiment of the present disclosure, a sum of an overlapping area of the plurality of first circuit patterns of the plurality of sub-pixels with the second sub-pixel opening and an overlapping area of the plurality of first circuit patterns of the plurality of sub-pixels with the third sub-pixel opening is smaller than an overlapping area of the plurality of first circuit patterns with the first sub-pixel opening.

In the display panel provided by at least one embodiment of the present disclosure, the plurality of first circuit patterns include circuit patterns of the plurality of sub-pixels which are configured to be connected to gate scanning signals.

In the display panel provided by at least one embodiment of the present disclosure, an orthographic projection of at least part of the first circuit patterns of at least two of the first sub-pixel circuit, the second sub-pixel circuit and the third sub-pixel circuit on the base substrate overlaps with an orthographic projection of the first sub-pixel opening on the base substrate.

In the display panel provided by at least one embodiment of the present disclosure, an orthographic projection of the first circuit pattern of the third sub-pixel on the base substrate is located outside an orthographic projection of the third sub-pixel opening on the base substrate.

In the display panel provided by at least one embodiment of the present disclosure, an orthographic projection of the first circuit pattern of the second sub-pixel on the base substrate is located outside an orthographic projection of the second sub-pixel opening on the base substrate.

In the display panel provided by at least one embodiment of the present disclosure, an orthographic projection of at least part of each of the first circuit pattern of the first sub-pixel, the first circuit pattern of the second sub-pixel and the first circuit pattern of the third sub-pixel on the base substrate overlaps with an orthographic projection of the first sub-pixel opening on the base substrate.

In the display panel provided by at least one embodiment of the present disclosure, an orthographic projection of the second circuit pattern of the third sub-pixel on the base substrate is located outside an orthographic projection of the third sub-pixel opening on the base substrate and overlaps with an orthographic projection of at least one of the first sub-pixel opening and the second sub-pixel opening on the base substrate.

In the display panel provided by at least one embodiment of the present disclosure, a plurality of second circuit patterns of the plurality of sub-pixels include circuit patterns configured to be connected to data signals.

In the display panel provided by at least one embodiment of the present disclosure, an orthographic projection of a portion of the first conductive layer on the base substrate overlaps with an orthographic projection of the first sub-pixel opening on the base substrate, and the portion of the first conductive layer includes a plurality of wires having substantially the same line width, and spacings between adjacent wires among the plurality of wires is substantially the same.

In the display panel provided by at least one embodiment of the present disclosure, a difference between the line width of each of the plurality of wires and an average line width of the plurality of wires is smaller than 20% of the average line width, and a difference between a spacing of every two adjacent wires and an average spacing of different adjacent wires is smaller than 20% of the average spacing.

In the display panel provided by at least one embodiment of the present disclosure, the second conductive layer includes a first portion and a second portion, and orthographic projections of the first portion and the second portion on the base substrate overlap with orthographic projections of the first sub-pixel opening and the second sub-pixel opening on the base substrate, respectively, and the first portion includes a plurality of first wires, wherein the plurality of first wires have substantially the same first line width, and adjacent first wires have substantially the same first spacing; and the second portion includes a plurality of second wires, wherein the plurality of second wires have substantially the same second line width, and adjacent second wires have substantially the same second spacing.

In the display panel provided by at least one embodiment of the present disclosure, the first line width and the second line width are different from each other, and the first spacing and the second spacing are different from each other.

In the display panel provided by at least one embodiment of the present disclosure, an orthographic projection of at least one of the active pattern of the second sub-pixel circuit and the active pattern of the third sub-pixel circuit on the base substrate overlaps with an orthographic projection of the first sub-pixel opening on the base substrate.

In the display panel provided by at least one embodiment of the present disclosure, orthographic projections of the active pattern of the second sub-pixel circuit and the active pattern of the third sub-pixel circuit on the base substrate are both located outside orthographic projections of the second sub-pixel opening and the third sub-pixel opening on the base substrate.

In the display panel provided by at least one embodiment of the present disclosure, orthographic projections of the active patterns of the first sub-pixel circuit, the second sub-pixel circuit and the third sub-pixel circuit on the base substrate each overlap with an orthographic projection of the first sub-pixel opening on the base substrate.

In the display panel provided by at least one embodiment of the present disclosure, an orthographic projection of the active pattern of the second sub-pixel circuit on the base substrate is located outside an orthographic projection of the second sub-pixel opening on the base substrate, and orthographic projections of the active pattern of the second sub-pixel circuit and the active pattern of the first sub-pixel circuit on the base substrate both overlap with an orthographic projection of the first sub-pixel opening on the base substrate.

In the display panel provided by at least one embodiment of the present disclosure, an orthographic projection of the active pattern of the third sub-pixel circuit on the base substrate overlaps with an orthographic projection of the third sub-pixel opening on the base substrate, and the orthographic projection of the third sub-pixel opening on the base substrate is located within a range of an orthographic projection of the active pattern of the third sub-pixel circuit on the base substrate.

In the display panel provided by at least one embodiment of the present disclosure, at least one of the first conductive layer, the second conductive layer and the active material layer includes a block pattern, and an orthographic projection of a part of the block pattern on the base substrate overlaps with an orthographic projection of a sub-pixel opening on the base substrate; and the block pattern includes a body portion and a plurality of strip portions, wherein a hollowed-out portion is arranged between the plurality of strip portions, and the plurality of strip portions are connected with each other through the body portion, wherein an orthographic projection of the body portion on the base substrate is located outside an orthographic projection of the sub-pixel opening, and an orthographic projection of at least part of the plurality of strip portions on the base substrate overlaps with the orthographic projection of the sub-pixel opening.

In the display panel provided by at least one embodiment of the present disclosure, the plurality of strip portions have substantially the same width.

The display panel provided by at least one embodiment of the present disclosure, further includes at least one of following features: the first conductive layer further includes a first dummy pattern, which is arranged in a gap region of the first circuit patterns of the plurality of sub-pixels, and an orthographic projection of the first dummy pattern on the base substrate overlaps with an orthographic projection of at least one of the first sub-pixel opening, the second sub-pixel opening and the third sub-pixel opening on the base substrate; the second conductive layer further includes a second dummy pattern, which is arranged in a gap region of the second circuit patterns of the plurality of sub-pixels, and an orthographic projection of the second dummy pattern on the base substrate overlaps with an orthographic projection of at least one of the first sub-pixel opening, the second sub-pixel opening and the third sub-pixel opening on the base substrate; and the active material layer further includes a third dummy pattern, which is arranged in a gap region of the active patterns of the plurality of sub-pixels, and an orthographic projection of the third dummy pattern on the base substrate overlaps with an orthographic projection of at least one of the first sub-pixel opening, the second sub-pixel opening and the third sub-pixel opening on the base substrate.

In the display panel provided by at least one embodiment of the present disclosure, the first dummy pattern and the second dummy pattern are electrically floating or connected to a fixed potential.

In the display panel provided by at least one embodiment of the present disclosure, the first circuit pattern includes a wire pattern adjacent to the first dummy pattern, the first dummy pattern and the wire pattern have substantially the same width, and spacings between adjacent patterns among the first dummy patterns and the wire patterns are substantially the same.

In the display panel provided by at least one embodiment of the present disclosure, the second circuit pattern includes a wire pattern adjacent to the second dummy pattern, the second dummy pattern and the wire pattern have substantially the same width, and spacings between adjacent patterns among the second dummy patterns and the wire patterns are substantially the same.

In the display panel provided by at least one embodiment of the present disclosure, the area of the first sub-pixel opening is greater than the area of the second sub-pixel opening, and the area of the second sub-pixel opening is greater than the area of the third sub-pixel opening.

In the display panel provided by at least one embodiment of the present disclosure, the first sub-pixel is a blue sub-pixel, one of the second sub-pixel and the third sub-pixel is a green sub-pixel, and the other one of the second sub-pixel and the third sub-pixel is a red sub-pixel.

In the display panel provided by at least one embodiment of the present disclosure, the planarization layer includes a first flat portion, a second flat portion and a third flat portion, and orthographic projections of the first sub-pixel opening, the second sub-pixel opening and the third sub-pixel opening on the base substrate are respectively located within ranges of orthographic projections of the first flat portion, the second flat portion and the third flat portion on the base substrate, wherein the first flat portion, the second flat portion and the third flat portion respectively have a first flat surface, a second flat surface and a third flat surface close to the light-emitting device, and at least two of the first flat surface, the second flat surface and the third flat surface are located at different level heights relative to a main surface of the base substrate.

In the display panel provided by at least one embodiment of the present disclosure, a distance between the first flat surface and the main surface of the base substrate is greater than a distance between the second flat surface and the main surface of the base substrate, in a direction perpendicular to the main surface of the base substrate.

In the display panel provided by at least one embodiment of the present disclosure, the distance between the second flat surface and the main surface of the base substrate is greater than or substantially equal to a distance between the third flat surface and the main surface of the base substrate in the direction perpendicular to the main surface of the base substrate.

At least one embodiment the present disclosure provides a display panel including: a base substrate; a plurality of sub-pixels, disposed on the base substrate, wherein each sub-pixel includes a light-emitting device and a sub-pixel circuit for driving the light-emitting device to emit light, and the plurality of sub-pixels include a first sub-pixel, a second sub-pixel and a third sub-pixel for displaying different colors; a pixel circuit layer, including sub-pixel circuits of the plurality of sub-pixels, and including a first sub-pixel circuit, a second sub-pixel circuit and a third sub-pixel circuit for respectively driving light-emitting devices of the first sub-pixel, the second sub-pixel and the third sub-pixel to emit light; a planarization layer, disposed on a side of the pixel circuit layer away from the base substrate; and a pixel defining layer, disposed on a side of the planarization layer away from the pixel circuit layer, and having a plurality of sub-pixel openings, wherein each sub-pixel opening is configured to define a light-emitting region of a corresponding sub-pixel, and at least a part of the light-emitting device of each sub-pixel is located in a corresponding sub-pixel opening, wherein the plurality of sub-pixel openings include a first sub-pixel opening, a second sub-pixel opening and a third sub-pixel opening corresponding to the first sub-pixel, the second sub-pixel and the third sub-pixel, respectively; wherein the pixel circuit layer includes a plurality of pattern layers, a first pattern layer among the plurality of pattern layers includes a plurality of first patterns of the plurality of sub-pixels, and orthographic projections of the plurality of first patterns on the base substrate overlap with an orthographic projection of at least one of the first sub-pixel opening, the second sub-pixel opening and the third sub-pixel opening on the base substrate; and an overlapping area of the plurality of first patterns with the first sub-pixel opening is greater than an overlapping area of the plurality of first patterns with the second sub-pixel opening or an overlapping area of the plurality of first patterns with the third sub-pixel opening.

In the display panel provided by at least one embodiment of the present disclosure, an overlapping area of the plurality of first patterns with at least one of the second sub-pixel opening and the third sub-pixel opening is zero.

In the display panel provided by at least one embodiment of the present disclosure, the plurality of first patterns include circuit patterns of the plurality of sub-pixels which are configured to be connected to a same type of signal.

In the display panel provided by at least one embodiment of the present disclosure, an area of the first sub-pixel opening is greater than an area of the second sub-pixel opening, and the area of the second sub-pixel opening is greater than an area of the third sub-pixel opening.

In the display panel provided by at least one embodiment of the present disclosure, the plurality of pattern layers further include a second pattern layer located on a side of the first pattern layer close to or away from the light-emitting device, the second pattern layer includes a plurality of second patterns of the plurality of sub-pixels, and an overlapping area of the plurality of second patterns with the first sub-pixel opening is greater than an overlapping area of the plurality of second patterns with the second sub-pixel opening or the third sub-pixel opening.

In the display panel provided by at least one embodiment of the present disclosure, the overlapping area of the plurality of second patterns with the second sub-pixel opening is zero.

In the display panel provided by at least one embodiment of the present disclosure, the overlapping area of the plurality of second patterns with the third sub-pixel opening is zero or equal to the area of the third sub-pixel opening.

In the display panel provided by at least one embodiment of the present disclosure, the plurality of pattern layers include one or more gate layers, one or more source/drain electrode layers, and one or more active material layers.

At least one embodiment of the present disclosure provides a display device, including any one of the above-mentioned display panel.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1A is a schematic cross-sectional view illustrating a patterned layer formed on a base substrate; FIG. 1B is a schematic cross-sectional view illustrating forming a planarization layer on a base substrate having a patterned layer.

FIG. 2A and FIG. 2B are schematic cross-sectional views illustrating a display panel according to some embodiments of the present disclosure.

FIG. 3A to FIG. 3E are schematic diagrams illustrating a planar arrangement of a first conductive layer in a pixel circuit layer and a plurality of sub-pixel openings of a display panel according to some embodiments of the present disclosure.

FIGS. 4A to 4E are schematic diagrams illustrating a planar arrangement of a second conductive layer in a pixel circuit layer and a plurality of sub-pixel openings of a display panel according to some embodiments of the present disclosure.

FIGS. 5A to 5C are schematic diagrams illustrating a planar arrangement of an active material layer in a pixel circuit layer and a plurality of sub-pixel openings of a display panel according to some embodiments of the present disclosure.

FIG. 6 is a schematic diagram illustrating a planar arrangement of part of pixel circuit patterns in a pixel circuit layer and a sub-pixel opening of a display panel according to some embodiments of the present disclosure.

FIG. 7 is a schematic plan view illustrating a display panel according to some embodiments of the present disclosure.

FIG. 8 is a schematic diagram illustrating a display device according to some embodiments of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., used in the present disclosure are not intended to indicate any sequence, amount or importance, but distinguish different components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not limited to a physical connection or mechanical connection, but may also include an electrical connection, directly or indirectly.

In various display devices, components such as pixel circuit devices (e.g., thin film transistors, etc.), light-emitting devices, photoelectric sensing elements, etc. may be included. These components usually include a plurality of inorganic material layers (e.g., metal, semiconductor, insulating material, etc.) and/or organic material layers, and these material layers are usually patterned, for example, having patterns of linear, block, strip and other shapes. These patterns may overlap with each other on the base substrate, the arrangement of the patterns in respective layers may be different in different regions, and the patterns in different regions may also be overlapped in different manners, resulting in that the overall pattern may be uneven. In some embodiments, after the respective patterned layer(s) is/are formed on the base substrate, a planarization process is performed to provide a flat surface for subsequent processes. The planarization process usually includes coating a planarization material (e.g., a photoresist material) on the base substrate to cover the patterned layer; the coating process includes applying a liquid planarization material on the base substrate, so as to achieve a planarization effect by means of leveling characteristics of the liquid planarization material, and then curing the planarization material to form a planarization layer. However, due to the uneven topography of the patterned layer, especially when the patterned layer has an excessively large step difference, it may be difficult for a single-layer of planarization material to meet the requirements of planarization; or it may be necessary to use a sufficiently thick planarization material to achieve the required flatness, which, however, will increase the difficulty of the subsequent process.

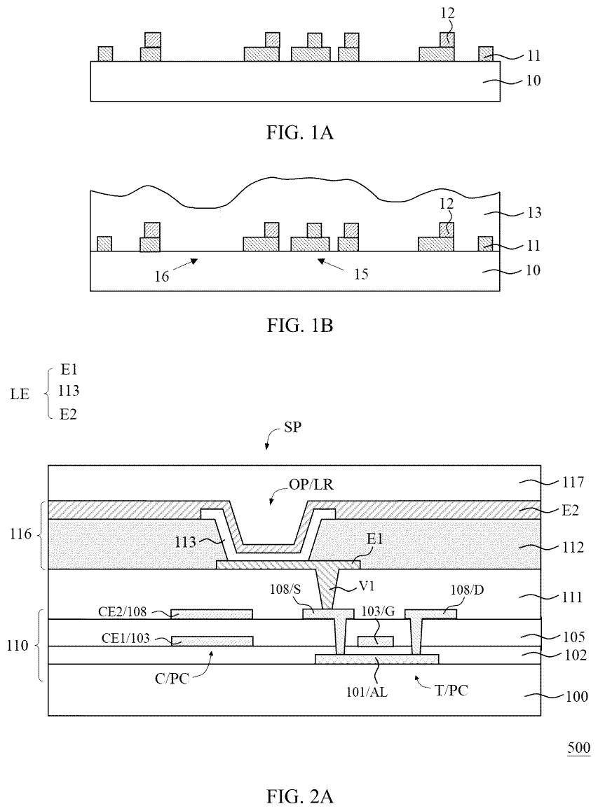

For example, FIG. 1A is a schematic cross-sectional view illustrating a patterned layer formed on a base substrate; FIG. 1B is a schematic cross-sectional view illustrating forming a planarization layer on a base substrate having a patterned layer.

As shown in FIG. 1A, one or more patterned layers, for example, including a first patterned layer 11 and a second patterned layer 12, are formed on a base substrate 10. Some parts of the first patterned layer 11 and the second patterned layer 12 overlap with each other in a direction perpendicular to the base substrate 10. The patterned layers 11 and 12 have uneven morphology, and the highest point of the patterned layers is the position where the first patterned layer 11 and the second patterned layer 12 are overlapped, which has a step difference al relative to the surface of the base substrate 10. Hereinafter, unless otherwise defined, the step difference of the patterned layers refers to a distance between a main surface of the patterned layers away from the base substrate and a main surface of the base substrate. It should be understood that other insulating layers or functional layers may be provided between the first patterned layer 11 and the second patterned layer 12, and for the sake of simplicity, only the patterned layers that will affect the flatness of the subsequently formed planarization layer are shown in FIG. 1A and FIG. 1B.

As shown in FIG. 1B, a planarization layer 13 is formed on the base substrate 10 to cover the first patterned layer 11 and the second patterned layer 12. However, since each pattern of the first patterned layer 11 and the second patterned layer 12 has a certain step difference relative to the base substrate 10, and the arrangement of each pattern is different in different regions of the base substrate 10, the formed planarization layer 13, as a whole, will still present an uneven morphology.

In some embodiments, the surface morphology of the planarization layer 13 (e.g., a variation of surface height thereof relative to the main surface of the base substrate) may not be completely consistent with the morphology of the patterned layer located underlying the planarization layer 13. For example, the position where the planarization layer has the greatest surface height may not correspond to the position where the patterned layer has the largest step difference, but may correspond to a dense pattern region of the patterned layer, for example, a region where an area of the patterns in a same layer is largest and/or the overlapping area of the patterns is the largest; while for a region in which the patterns are sparsely arranged, the planarization layer overlying this region has a smaller height. For example, as shown in FIG. 1B, the planarization layer 13 located above the dense pattern region 15 of the patterned layer has a height greater than other regions. The reason for the formation of such surface morphology of the planarization layer 13 is that, the planarization process utilizes wet coating for film formation and then utilizes leveling characteristics of material for planarization. The leveling characteristics of the material are related to the shape and area of the bottom patterns. For regions where the bottom patterns are arranged densely (i.e., the area occupied by the patterns is larger), more planarization material can be accumulated, which leads to a greater height of the formed planarization layer; while in the regions where the bottom patterns are arranged sparsely, the area occupied by the patterns is smaller, and the planarization material is difficult to be effectively retained at high positions but will flow and level towards the depressions due to its leveling characteristics, which makes the planarization layer have smaller height in these regions.

On the other hand, in the dense pattern region 15 of the patterned layer, the flatness of the planarization layer 13 is relatively higher, that is, it has a relatively flat surface; while for a region 16 where the patterns of the patterned layer are most sparsely arranged (e.g., a region where no pattern is arranged basically), the planarization layer 13 located above this region also has a relatively high flatness because this region is barely provided with patterns which may result in an uneven morphology. In the present disclosure, the flatness of the planarization layer refers to the degree of how the planarization layer is flat; that is, the higher the flatness is, the flatter the surface of the planarization layer will be.

In addition, in some embodiments, the flatness of the planarization layer can also be improved by adjusting the uniformity of arrangement of patterns of the patterned layer, for example, by setting the patterns to have equal line widths and equal spacings. That is, the flatness of the planarization layer can be improved by adjusting the density and/or uniformity of arrangement of patterns of the patterned layer.

The OLED display panel includes a plurality of sub-pixels, and includes a pixel circuit layer, a light-emitting device layer, and a planarization layer arranged between the pixel circuit layer and the light-emitting device layer; in some embodiments, the planarization layer is configured to reduce or shield the influence of the morphology of a plurality of patterned layers in the pixel circuit layer on the light-emitting devices, and to provide a flat surface for the light-emitting devices, so that at least a portion of the light-emitting device located in the light-emitting region is formed on a flat surface with high flatness, thereby ensuring the uniformity of light emission of the light-emitting regions in various sub-pixels and improving the display quality of the display panel.

According to materials and process capabilities for the planarization layer in the existing technology, it may not be possible to improve the flatness of the planarization layer only by improving the planarization process to meet the requirements of subsequent process steps and/or device performance. In the embodiment of the present disclosure, by optimizing the arrangement of pixel circuit patterns in the pixel circuit layer, the flatness of the surface of the planarization layer corresponding to sub-pixel opening regions can be improved, so that at least a portion of the light-emitting device located in each sub-pixel opening region is formed on a flat surface with high flatness, thereby improving the uniformity of light emission of light-emitting devices in the light-emitting regions of various sub-pixels and improving the display quality of the display panel.

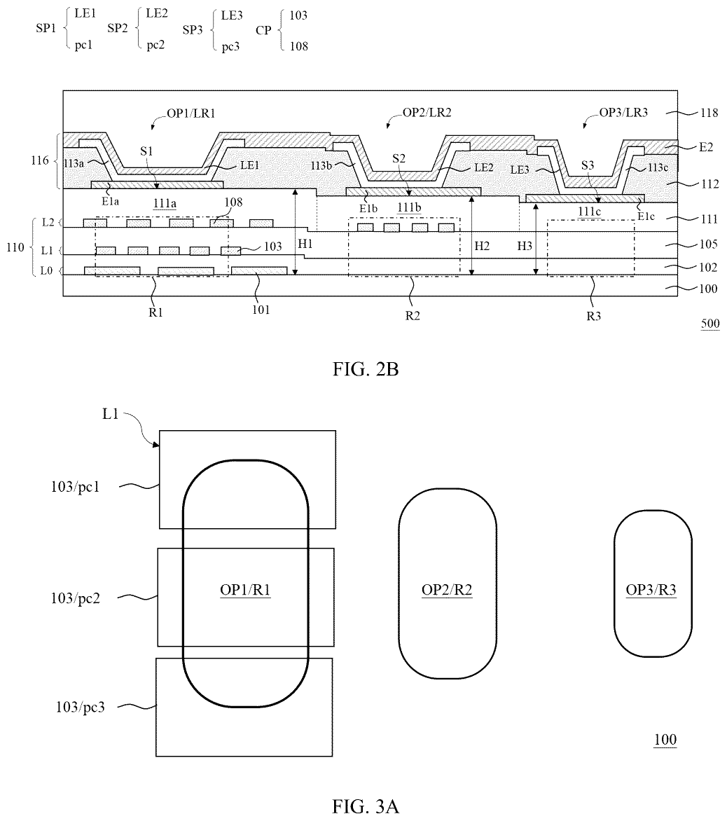

FIG. 2A is a schematic cross-sectional view illustrating a display panel according to some embodiments of the present disclosure. FIG. 2B is another schematic cross-sectional view illustrating a display panel according to some embodiments of the present disclosure.

Referring to FIG. 2A and FIG. 2B, in some embodiments, a display panel 500 includes a base substrate 100 and a plurality of pixel units arranged in an array on the base substrate 100, and each pixel unit may include a plurality of sub-pixels SP for displaying different colors. In some embodiments, each sub-pixel includes a light-emitting device LE and a sub-pixel circuit PC connected with each other, and the sub-pixel circuit PC is configured to drive the corresponding light-emitting device LE to emit light. FIG. 2A is a schematic cross-sectional view illustrating a structure of a sub-pixel SP. Various sub-pixels have similar structures, but the positional relationship between the light-emitting device and the sub-pixel circuit may be different for different sub-pixels. FIG. 2B is a schematic cross-sectional view illustrating three sub-pixels in one pixel unit. It should be understood that the display panel 500 may include any suitable number of pixel units, and the number of sub-pixels included in each pixel unit is not limited.

Referring to FIG. 2A and FIG. 2B, in some embodiments, the display panel 500 includes a pixel circuit layer 110, a pixel defining layer 112, and a light-emitting device layer 116. The pixel circuit layer 110 is disposed on a side of the base substrate 100 and includes a plurality of sub-pixel circuits PC, of a plurality of sub-pixels, for driving corresponding light-emitting devices to emit light. The pixel defining layer 112 may be disposed on a side of the pixel circuit layer 110 away from the base substrate 100 and has a plurality of sub-pixel openings OP, and each sub-pixel opening OP is configured to define a light-emitting region LR of a corresponding sub-pixel. The light-emitting device layer 116 includes light-emitting devices LE of a plurality of sub-pixels SP, and at least part of the light-emitting device LE of each sub-pixel SP is located in the corresponding sub-pixel opening OP. That is, the light-emitting region LR of each sub-pixel includes a portion of the light-emitting device LE located in the corresponding sub-pixel opening OP.

In some embodiments, the sub-pixel circuit PC of each sub-pixel is disposed in the pixel circuit layer 110 and includes, for example, one or more thin film transistors T and capacitor(s) C. Only one thin film transistor T and one capacitor C are schematically shown in FIG. 2A, but it should be understood that each sub-pixel circuit can adopt any suitable circuit structure, e.g., a pixel circuit such as 2TIC, 3TIC, 6TIC, 7TIC, 8TIC, 10TIC, 6T2C, 7T2C, 8T2C, or 10T2C pixel circuit, or the like. The pixel circuit of each sub-pixel can be configured and adjusted according to product designs and requirements. For example, each thin film transistor T includes a gate electrode G, an active layer AL, a source electrode S and a drain electrode D. In some embodiments, the source electrode S and the drain electrode D are collectively referred to as a source/drain electrode S/D. Each capacitor C may include electrode plates CE1 and CE2 opposite to each other.

In some embodiments, the pixel circuit layer 110 is further provided with a plurality of conductive wires, such as one or more of gate signal lines, data signal lines, common electrode lines, detection signal lines, power supply voltage lines, auxiliary connection lines and the like. The plurality of conductive wires are connected to the thin film transistor(s) and capacitor(s) of the corresponding sub-pixels to apply corresponding signals to the corresponding thin film transistor(s) and capacitor(s) and/or to connect corresponding electrodes of the thin film transistor(s) and capacitor(s) to a common electrode terminal, a voltage terminal, or the like. The conductive wires in the pixel circuit layer may include any wire required by the pixel circuit, and the type and number of the conductive wires are not limited in the present disclosure. Each sub-pixel circuit includes thin film transistor(s) and capacitor(s), as well as at least part of conductive wires connected to the thin film transistor(s) and the capacitor(s).

The pixel circuit layer 110 includes a plurality of layers of circuit patterns and active patterns (collectively referred to as pixel circuit patterns). The plurality of layers of circuit patterns may include, for example, one or more of the following: gate electrodes and source/drain electrodes of thin film transistors of a plurality of sub-pixel circuits, electrode plates of capacitors of a plurality of sub-pixel circuits, and the above-mentioned plurality of conductive wires. The active patterns may include active layers of thin film transistors of a plurality of sub-pixel circuits, or may further include component patterns such as electrode plates of capacitors.

Referring to FIG. 2B, in some embodiments, the display substrate 500 may include sub-pixels SP1, SP2 and SP3 for displaying different colors. For example, the sub-pixel SP1 may be a blue sub-pixel, and the sub-pixels SP2 and SP3 may be a green sub-pixel and a red sub-pixel, respectively, or vice versa. The sub-pixel SP1 includes a light-emitting device LE1 and a sub-pixel circuit pc1 for driving the light-emitting device LE1 to emit light. The sub-pixel SP2 includes a light-emitting device LE2 and a sub-pixel circuit pc2 for driving the light-emitting device LE2 to emit light. The sub-pixel SP3 includes a light-emitting device LE3 and a sub-pixel circuit pc3 for driving the light-emitting device LE3 to emit light. In some embodiments, the sub-pixels SP1, SP2 and SP3 may also be referred to as a first sub-pixel, a second sub-pixel and a third sub-pixel, respectively, but the present disclosure is not limited thereto.

In some embodiments, the pixel defining layer 112 has sub-pixel openings OP1, OP2 and OP3, which are configured to define light-emitting regions LR1, LR2 and LR3 of corresponding sub-pixels SP1, SP2 and SP3, respectively. At least parts of the light-emitting devices LE1-LE3 of respective sub-pixels SP1-SP3 are located in the corresponding sub-pixel openings OP1-OP3. In some embodiments, the sub-pixel openings OP1, OP2 and OP3 may also be referred to as a first sub-pixel opening, a second sub-pixel opening and a third sub-pixel opening, respectively, but the present disclosure is not limited thereto.

In some embodiments, for example, since the materials of sub-pixels of different colors may be different in their performances (e.g., luminous efficiency, service life, etc.), the design of areas, shapes and the like may be different for different sub-pixel openings (i.e., light-emitting regions).

For example, the sub-pixel openings OP1-OP3 may have different sizes (e.g., width, area, etc.). For example, the area of the sub-pixel opening OP1 of the sub-pixel SP1 (e.g., blue sub-pixel) may be greater than the areas of the sub-pixel openings OP2 and OP3 of other sub-pixels (e.g., green and red sub-pixels). The area of the sub-pixel opening OP2 of the sub-pixel SP2 (e.g., green sub-pixel) may be greater than the area of the sub-pixel opening OP3 of the sub-pixel SP3 (e.g., red sub-pixel). In some other embodiments, the area of the sub-pixel opening of the green sub-pixel may also be smaller than the area of the sub-pixel opening of the red sub-pixel. In the present disclosure, unless otherwise defined, the size (e.g. width, area) of the sub-pixel opening refers to the size of the sub-pixel opening in a direction parallel to the main surface of the base substrate, and the area of the sub-pixel opening is equal to the area of the orthographic projection of the sub-pixel opening on the main surface of the base substrate; the orthographic projection of a component on the main surface of the base substrate refers to the projection of the component on the base substrate in a direction perpendicular to the main surface of the base substrate.

In some embodiments, the pixel circuit layer 110 includes regions R1, R2 and R3 corresponding to the sub-pixel openings OP1, OP2 and OP3, respectively, and the orthographic projections of the regions R1, R2 and R3 on the base substrate 100 coincide with the orthographic projections of the sub-pixel openings OP1, OP2 and OP3 (i.e., light-emitting regions LR1, LR2 and LR3) on the base substrate 100, respectively. In the present disclosure, the orthographic projections of two components coinciding with each other represents that the orthographic projections of the two components have the same boundary. In some embodiments, the regions R1, R2 and R3 may also be referred to as a first region, a second region and a third region of the pixel circuit layer 110, respectively.

In some embodiments, the pixel circuit patterns of the pixel circuit layer 110 include a plurality of circuit patterns CP and active patterns 101, and in each layer, the density of pixel circuit patterns may be different in different regions R1-R3 of the pixel circuit layer 110. The embodiment of the present disclosure can optimize the arrangement of pixel circuit patterns in each layer, especially the arrangement of pixel circuit patterns located in regions R1-R3 overlapping with the respective sub-pixel openings, for example, according to the design differences, such as the sizes of different sub-pixels, so as to improve the flatness of the planarization layer located above the pixel circuit layer in the corresponding regions.

In the present disclosure, the density of pixel circuit patterns in each region represents the proportion of the area of the pixel circuit patterns in each region, that is, the ratio of the area of the pixel circuit patterns located in the region to the area of the region. For pixel circuit patterns in each layer, the area of the pixel circuit patterns in each of the regions R1-R3 is equal to the area of the orthographic projection of the pixel circuit patterns located in this region on the base substrate, and equal to the area of these pixel circuit patterns overlapping with the corresponding sub-pixel opening; the areas of the regions R1-R3 are respectively equal to the areas of the orthographic projections of the corresponding sub-pixel openings OP1-OP3 on the base substrate.

For example, the pixel circuit layer 110 includes a first conductive layer including a plurality of first circuit patterns of a plurality of sub-pixels, wherein the density of the plurality of first circuit patterns in the region R3 of the pixel circuit layer 110 may be smaller than the density of the plurality of first circuit patterns in the region RI or R2. For example, the orthographic projection of a plurality of first circuit patterns on the base substrate 100 overlaps with the orthographic projection of at least one of the sub-pixel openings OP1 to OP3 on the base substrate; the ratio of the overlapping area of the plurality of first circuit patterns with the sub-pixel opening OP3 to the area of the sub-pixel opening OP3 (i.e., equivalent to the density of the first circuit patterns in the region R3) is smaller than the ratio of the overlapping area of the plurality of first circuit patterns with the sub-pixel opening OP1 to the area of the sub-pixel opening OP1 (i.e., equivalent to the density of the first circuit patterns in the region R1), or the ratio of the overlapping area of the plurality of first circuit patterns with the sub-pixel opening OP2 to the area of the sub-pixel opening OP2 (i.e., equivalent to the density of the first circuit patterns in the region R2). Here, each of the overlapping areas of the first circuit patterns with the sub-pixel openings OP1-OP3 refers to the area of a portion of the orthographic projection of the first circuit patterns on the base substrate overlapping with the orthographic projection of the corresponding one of the sub-pixel openings OP1-OP3 on the base substrate, and equal to the area of the orthographic projection of the first circuit patterns located in the corresponding one of regions R1-R3 on the base substrate. The first conductive layer may be the layer where the gate electrodes or the source/drain electrodes of the thin film transistors of a plurality of sub-pixel circuits are located, and may further include one or more of the electrode plates of the capacitors and a plurality of conductive wires. For example, the pixel circuit layer includes a plurality of pattern layers, and each pattern layer includes a plurality of patterns, and the first conductive layer may be the uppermost pattern layer among the plurality of pattern layers which is closest to the light-emitting device layer in the direction perpendicular to the main surface of the base substrate, or the first conductive layer is located at a side of the uppermost pattern layer among the plurality of pattern layers away from the light-emitting devices.

In some embodiments, at least two of the overall densities of the circuit patterns CP arranged in the regions R1, R2 and R3 may be different from each other. For example, the overall density of the circuit patterns CP arranged in the region R1 is greater than the overall density of the circuit patterns CP arranged in the region R2 or the overall density of the circuit patterns CP arranged in the region R3. For example, the overall density of the circuit patterns arranged in the region R2 may be greater than or substantially equal to the overall density of the circuit patterns arranged in the region R3. In some embodiments, the pixel circuit layer includes a plurality of layers of circuit patterns, and the overall density of the circuit patterns in each region of the pixel circuit layer is the sum of the densities of the various layers of circuit patterns in each region.

In some embodiments, the sub-pixel circuit patterns of a plurality of sub-pixels are concentratedly arranged at positions corresponding to some of the sub-pixel openings (e.g., in the region directly below some of the sub-pixel openings and the region adjacent thereto in the drawing), and there is substantially no circuit pattern arranged below some of the sub-pixel openings, so that the flatness of the bottom of each sub-pixel opening can be improved.

For example, among the sub-pixels SP1 to SP3, part of the circuit patterns (e.g., most of the circuit patterns) of the sub-pixel circuits pc1-pc3 of these sub-pixels are concentratedly arranged in the region R1 underlying the sub-pixel opening OP1 and regions adjacent to the region R1, part of the circuit patterns (e.g., a small part of the circuit patterns) are arranged in the region R2 underlying the sub-pixel opening OP2 and regions adjacent to the region R2, and there is substantially no circuit pattern arranged in the region R3 underlying the sub-pixel opening OP3. In some embodiments, the density of circuit patterns in each region may be substantially positively correlated with the size of the corresponding sub-pixel opening, that is, the larger the size of the sub-pixel opening is, the higher the density of the circuit patterns arranged in the corresponding region below the sub-pixel opening will be. In some embodiments, the density of the circuit patterns may be approaching zero in a region corresponding to the sub-pixel opening OP3 with a smaller size (e.g., the smallest size). However, the present disclosure is not limited thereto.

In some embodiments, the orthographic projection of at least part of at least one of the sub-pixels SP1-SP3 on the base substrate is located outside the orthographic projection of the corresponding sub-pixel opening(s) on the base substrate, and may overlap with the orthographic projection of one or more other sub-pixel openings on the base substrate. For example, the orthographic projection of at least part of the sub-pixel circuit pc3 of the sub-pixel SP3 on the base substrate 100 is located outside the orthographic projection of the sub-pixel opening OP3 on the base substrate 100, and may overlap with the orthographic projection of at least one of the sub-pixel openings OP1 and OP2 on the base substrate 100 and/or may be located in a region close to the orthographic projection of the sub-pixel opening OP1 or OP2 on the base substrate 100. The orthographic projection of at least part of the sub-pixel circuit pc2 of the sub-pixel SP2 on the base substrate 100 may be located outside the orthographic projection of the sub-pixel opening OP2 on the base substrate 100, and may overlap with the orthographic projection of the sub-pixel opening OP1 on the base substrate 100.

In some embodiments, the pixel circuit layer 110 includes an active material layer L0, a conductive layer L1, and a conductive layer L2. The conductive layer L1 and the conductive layer L2 may be referred to as a first conductive layer and a second conductive layer, respectively, or vice versa. The active material layer L0 includes a plurality of active patterns 101 (or referred to as active pattern groups) of a plurality of sub-pixels, the conductive layer L1 includes a plurality of circuit patterns 103 of a plurality of sub-pixels, and the conductive layer L2 includes a plurality of circuit patterns 108 of a plurality of sub-pixels. The circuit pattern 103 and the circuit pattern 108 may be referred to as a first circuit pattern and a second circuit pattern, respectively, or vice versa; the plurality of circuit patterns 103 and the plurality of circuit patterns 108 of the plurality of sub-pixels may also be referred to as a first circuit pattern group and a second circuit pattern group, respectively, or vice versa. For example, the conductive layer L1 is the layer where the gate electrodes G in the thin film transistors T of the sub-pixel circuits are located, the conductive layer L2 is the layer where the source/drain electrodes S/D in the thin film transistors T of the sub-pixel circuits are located, and the active material layer L0 is the layer where the active layers AL in the thin film transistors T of the sub-pixel circuits are located. It should be understood that the number of the material layers of the pixel circuit layer shown in the figure is only illustrative, and the present disclosure is not limited thereto. For example, the pixel circuit layer may further include one or more conductive layers other than the conductive layers L1 and L2.

The plurality of circuit patterns 103 may include circuit patterns of a plurality of sub-pixels which are similar in shapes, routing directions and/or connected to the same signals. For example, the plurality of circuit patterns 103 include circuit patterns of a plurality of sub-pixels which are configured to be connected to gate scanning signals. For example, the plurality of circuit patterns 103 may include gate electrodes G of a plurality of thin film transistors of a plurality of sub-pixels and conductive wires such as gate signal lines, compensation signal lines, auxiliary connection lines or the like which are connected to the gate electrodes G, or may further include conductive patterns such as electrode plates, auxiliary cathodes connected to the cathodes of light-emitting devices, or the like; the plurality of circuit patterns 108 may include circuit patterns of a plurality of sub-pixels which are similar in shapes, routing directions and/or connected to the same signals. For example, the plurality of circuit patterns 108 include circuit patterns of a plurality of sub-pixels which are configured to be connected to data signals. For example, the plurality of circuit patterns 108 include, for example, source/drain electrodes S/D of a plurality of thin film transistors of a plurality of sub-pixels, and conductive wires such as data signal lines, auxiliary connection lines, compensation signal lines or the like which are connected to the source/drain electrodes S/D, or may further include electrode plates, auxiliary cathodes connected to the cathodes of light-emitting devices, or the like; the plurality of active patterns 101 include, for example, active layers AL of a plurality of thin film transistors of a plurality of sub-pixels. In some embodiments, two electrode plates of a capacitor of each sub-pixel circuit may be located in two of the conductive layer L1, the conductive layer L2 and the active material layer L0; alternatively, one of the two electrode plates may be located in one of the conductive layer L1, the conductive layer L2 and the active material layer L0, and the other one electrode plate may be located in another conductive layer (e.g., another conductive layer located between the conductive layer L1 and the conductive layer L2). The present disclosure does not limit the position of the electrode plates of the capacitor.

For example, the sub-pixel circuit of each sub-pixel may include a circuit pattern 103 located at the conductive layer L1, a circuit pattern 108 located at the conductive layer L2, and an active pattern 101 located at the active material layer L0. In each sub-pixel circuit, the circuit pattern 103 includes gate electrodes and conductive wires such as gate lines, the second circuit pattern 103 includes source/drain electrodes and conductive wires such as data signal lines, and the active pattern 101 may include active layers AL; at least one of the circuit pattern 103, the circuit pattern 108 and the active pattern 101 may further include an electrode plate of a capacitor. Circuit patterns 103 of a plurality of sub-pixel circuits constitute a first circuit pattern group located at the conductive layer L1, circuit patterns 108 of a plurality of sub-pixel circuits constitute a second circuit pattern group located at the conductive layer L2, and active patterns 101 of a plurality of sub-pixel circuits constitute an active pattern group located at the active material layer L0.

In some embodiments, the display panel 500 further includes an insulating layer 102, an insulating layer 105 and a planarization layer 111 sequentially disposed on the base substrate 100. The insulating layer 102 is disposed on a side of the base substrate 100, and covers a sidewall of the active material layer L0 and a surface of the active material layer L0 at a side away from the base substrate 100. The insulating layer 102 is located between the active material layer L0 and the conductive layer L1, and may be used as the gate insulating layer of a plurality of thin film transistors. The insulating layer 105 is disposed on a side of the conductive layer L1 away from the base substrate 100, for example, between the conductive layer LI and the conductive layer L2, and covers a sidewall of the conductive layer LI and a surface of the conductive layer L1 at a side away from the base substrate 100. The planarization layer 111 is disposed between the pixel circuit layer 110 and the pixel defining layer 112, and between the pixel circuit layer 110 and the light-emitting device layer 116, for example, at a side of the conductive layer L2 away from the base substrate 100, and covers a sidewall of the conductive layer L2 and a surface of the conductive layer L2 at a side away from the base substrate 100. In other words, the active material layer L0 is located in the insulating layer 102, the first conductive layer 103 is located in the insulating layer 105, and the conductive layer L2 is located in the planarization layer 111. In some embodiments, the insulating layer 102, the insulating layer 105, and the planarization layer 111 are further provided with a plurality of via holes to provide electrical connections between various layers in the pixel circuit layer, and electrical connections between the pixel circuit layer and the light-emitting devices.

The planarization layer 111 is configured to provide a flat surface for the light-emitting device of each sub-pixel, for example, at least to provide a flat surface for each sub-pixel opening region, so that the light-emitting device of each sub-pixel is formed on the flat surface, thereby improving the uniformity of light emission of the light-emitting devices in various sub-pixels.

In some embodiments, the flatness of the planarization layer 111 in each region is influenced by various layers of circuit patterns/active patterns in this region. For example, the arrangement of the active patterns 101 of the active material layer L0 directly affects the flatness of the insulating layer 102 in respective regions, and affects the flatness of the overlying planarization layer 111; the arrangement of the circuit patterns 103 of the conductive layer L1 directly affects the flatness of the insulating layer 105 in respective regions, and further affects the flatness of the overlying planarization layer 111; and the arrangement of the circuit patterns 108 of the conductive layer L2 directly affects the flatness of the planarization layer 111. The embodiment of the present disclosure minimizes the influence of the pixel circuit patterns on the flatness of the planarization layer by optimizing the arrangement of various layers of pixel circuit patterns of the pixel circuit layer, so that at least respective portions of the planarizing layer 111 located above the regions R1-R3 of the pixel circuit layer each have a high flatness, and that the light-emitting devices LE1 to LE3 are each formed on a flat surface with high flatness, thereby improving the uniformity of light emission of various sub-pixels.

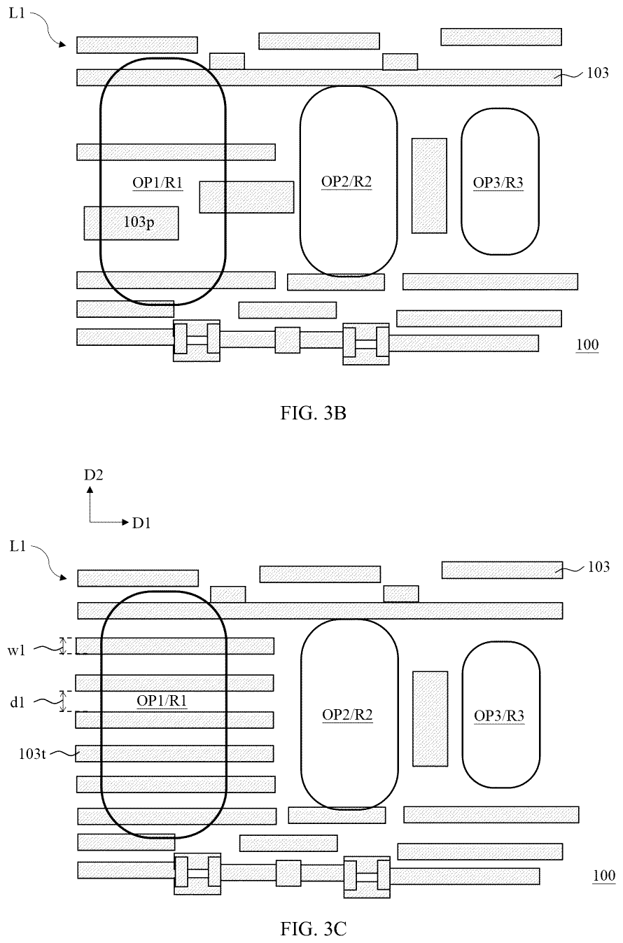

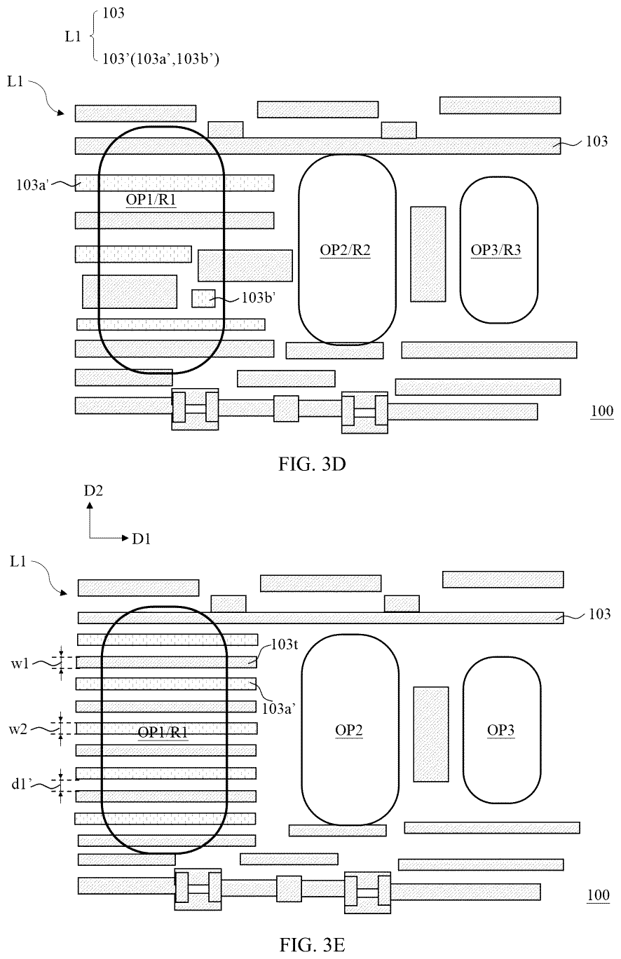

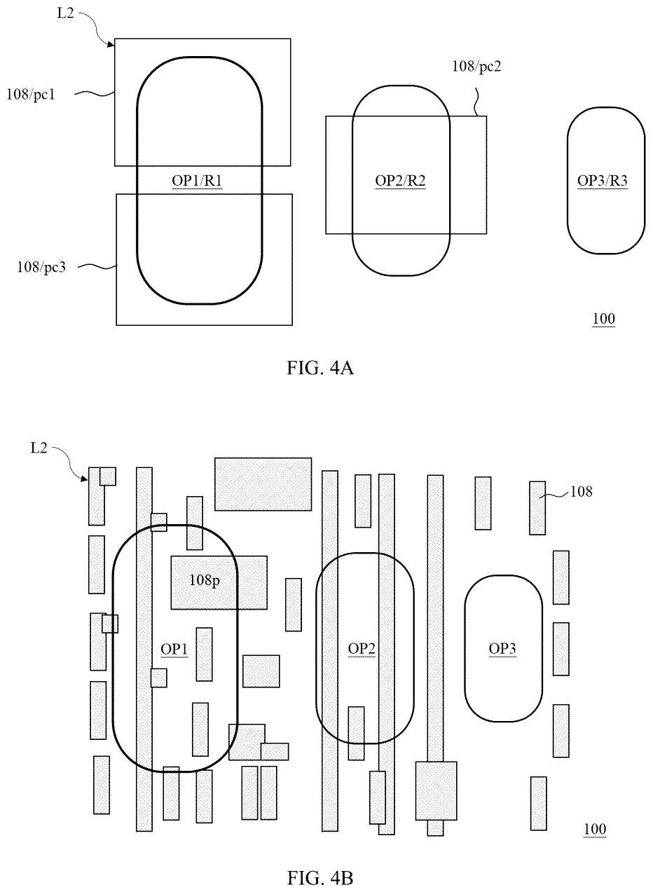

FIG. 3A is a schematic plan view illustrating a plurality of circuit patterns 103 of a conductive layer L1 and a plurality of sub-pixel openings OP1-OP3 in a display panel according to some embodiments of the present disclosure. FIG. 3B is a schematic plan view which more specifically illustrates a plurality of circuit patterns 103 of a conductive layer L1 and a plurality of sub-pixel openings OP1-OP3 in a display panel according to some embodiments of the present disclosure.

Referring to FIGS. 2A, 3A and 3B, in some embodiments, the densities of the plurality of circuit patterns 103 in regions R1-R3 of the pixel circuit layer 110 are different from each other. For example, in the conductive layer L1, the density of the circuit patterns 103 arranged in the region R1 is greater than the densities of the circuit patterns 103 arranged in the regions R2 and R3. That is, The ratio of the area of the orthographic projection of the circuit patterns 103 located in the region R1 on the base substrate 100 (equivalent to the overlapping area of the circuit patterns 103 with the sub-pixel opening OP1) to the area of the orthographic projection of the region R1 on the base substrate 100 (equivalent to the area of the sub-pixel opening OP1) is greater than the ratio of the area of the orthographic projection of the circuit patterns 103 located in the region R2 on the base substrate 100 (equivalent to the overlapping area of the circuit patterns 103 with the sub-pixel opening OP2) to the area of the orthographic projection of the region R2 on the base substrate 100 (equivalent to the area of the sub-pixel opening OP2), and is greater than the ratio of the area of the orthographic projection of the circuit patterns 103 located in the region R3 on the base substrate 100 (equivalent to the overlapping area of the circuit patterns 103 with the sub-pixel opening OP3) to the area of the orthographic projection of the region R3 on the base substrate 100 (equivalent to the area of the sub-pixel opening OP3). As described above, the orthographic projections of the regions R1 to R3 on the base substrate 100 coincide with the orthographic projections of the sub-pixel openings OP1 to OP3 on the base substrate 100, respectively. Therefore, the areas of the orthographic projections of the regions R1, R2 and R3 on the base substrate 100 are respectively equal to the areas of the orthographic projections of the sub-pixel openings OP1 to OP3 on the base substrate.

In some embodiments, the overlapping area of the plurality of circuit patterns 103 with the sub-pixel opening OP1 may be greater than the overlapping area of the plurality of circuit patterns 103 with the sub-pixel opening OP3 and/or greater than the overlapping area of the plurality of circuit patterns 103 with the sub-pixel opening OP2. In some embodiments, the overlapping area of the plurality of circuit patterns 103 with the sub-pixel opening OP1 may be greater than the sum of the overlapping area of the plurality of circuit patterns 103 with the sub-pixel opening OP3 and the overlapping area of the plurality of circuit patterns 103 with the sub-pixel opening OP2. For example, the overlapping area of the plurality of circuit patterns 103 with at least one of the sub-pixel openings OP2 and OP3 may be zero or approaching zero. That is, the orthographic projections of the plurality of circuit patterns 103 on the base substrate 100 may not overlap with at least one of the orthographic projections of the sub-pixel opening OP2 and the sub-pixel opening OP3 on the base substrate.

For example, the orthographic projection of at least part of the circuit patterns 103 of at least two of the sub-pixel circuits pc1 to pc3 on the base substrate 100 may overlap with the orthographic projection of the sub-pixel opening OP1 on the base substrate 100. For example, the orthographic projection of the circuit pattern 103 in the sub-pixel circuit pc3 of the sub-pixel SP3 on the base substrate 100 may be located outside the orthographic projection of the corresponding sub-pixel opening OP3 on the base substrate 100; the orthographic projection of the circuit pattern 103 in the sub-pixel circuit pc2 of the sub-pixel SP2 on the base substrate 100 may be located outside the orthographic projection of the corresponding sub-pixel opening OP2 on the base substrate 100; for example, the orthographic projection of the circuit pattern 103 of the sub-pixel circuit pc1 on the base substrate may overlap with the orthographic projection of the sub-pixel opening OP1 on the base substrate 100, and at least part of the orthographic projection of at least one of the circuit pattern 103 of the sub-pixel circuit pc2 and the circuit pattern 103 of the sub-pixel circuit pc3 on the base substrate 100 may also overlap with the orthographic projection of the sub-pixel opening OP1 on the base substrate 100 and/or may be located in the region close to the orthographic projection of the sub-pixel opening OP1 on the base substrate 100.

In some embodiments, the circuit patterns 103 of the sub-pixel circuits pc1 to pc3 may all be concentratedly arranged in the region R1 corresponding to the sub-pixel opening OP1 and in the region close to the region R1, and at least one of the regions R2 and R3 corresponding to the sub-pixel openings OP2 and OP3 may be substantially free of the circuit pattern 103. In some embodiments, the circuit patterns 103 overlapping with the sub-pixel opening OP1 in the direction perpendicular to the main surface of the base substrate (i.e., the circuit patterns 103 located in the region R1) may include the circuit pattern 103 of the sub-pixel circuit pc1, and may further include the circuit pattern(s) 103 of one or more of the sub-pixel circuits pc2 and pc3. It should be understood that, the arrangement shown in the drawing is only illustrative, and the present disclosure is not limited thereto, as long as the density of the circuit patterns 103 in each region is arranged in a similar manner as described above and the flatness corresponding to each sub-pixel opening region can be improved. In the case that the number of circuit patterns arranged in the conductive layer L1 is relatively small, the circuit patterns 103 of the sub-pixel circuits pc1-pc3 may all be concentratedly arranged in a region corresponding to the same sub-pixel opening; in some other cases that the number of patterns arranged in the conductive layer L1 is relatively large, the circuit patterns 103 of a plurality of sub-pixel circuits pc1-pc3 may also be concentratedly arranged in regions corresponding to two sub-pixel openings. That is, the circuit patterns 103 of the plurality of sub-pixel circuits pc1-pc3 may also overlap with two sub-pixel openings of the sub-pixel openings OP1-OP3, while the circuit patterns 103 may not be provided in the region overlapping with the other one sub-pixel opening.

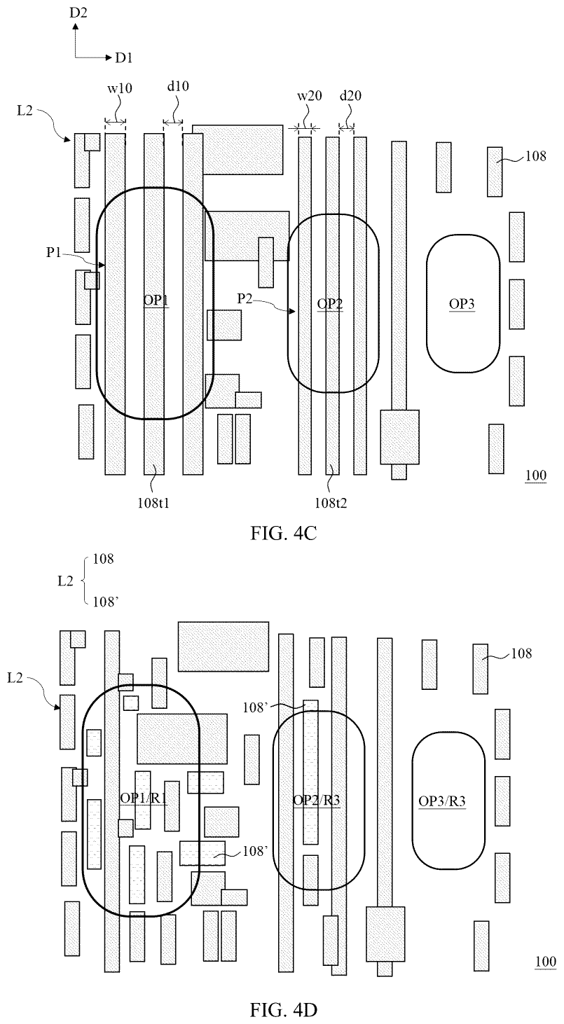

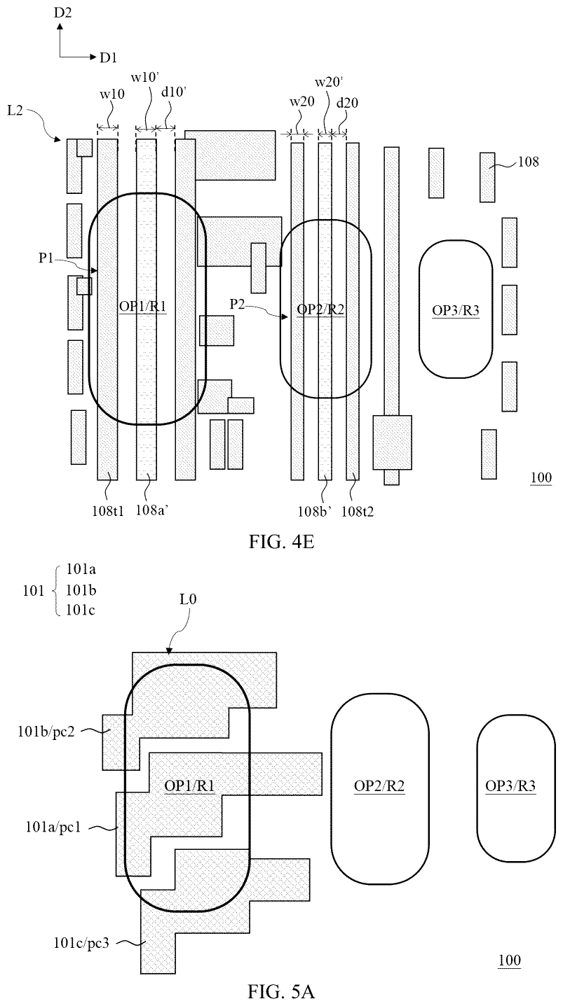

FIG. 4A and FIG. 4B are schematic plan views illustrating circuit patterns 108 of a plurality of sub-pixels in a conductive layer L2 and sub-pixel openings OP1-OP3 in some embodiments of the present disclosure.

Referring to FIGS. 2B, 4A and 4B, in some embodiments, the densities of the circuit patterns 108 of a plurality of sub-pixels may be different in regions R1-R3 of the pixel circuit layer 110. For example, the density of the circuit pattern(s) 108 in the region R3 may be smaller than the density of the circuit pattern(s) 108 in the region RI or the density of the circuit pattern(s) 108 in the region R2; and the densities of the circuit patterns 108 arranged in the region R1 and the region R2 may be the same as or different from each other.

That is to say, the ratio of the overlapping area of the circuit patterns 108 of a plurality of sub-pixels with the sub-pixel opening OP3 to the area of the sub-pixel opening OP3 is smaller than the ratio of the overlapping area of the circuit patterns 108 of a plurality of sub-pixels with the sub-pixel opening OP2 to the area of the sub-pixel opening OP2, and is smaller than the ratio of the overlapping area of the circuit patterns 108 of a plurality of sub-pixels with the sub-pixel opening OP1 to the area of the sub-pixel opening OP1. The ratio of the overlapping area of the first circuit patterns 108 with the sub-pixel opening OP1 to the area of the sub-pixel opening OP1, and the ratio of the overlapping area of the circuit patterns 108 with the sub-pixel opening OP2 to the area of the sub-pixel opening OP2 may be the same as or different from each other. In some embodiments, the overlapping area of the plurality of circuit patterns 108 with the sub-pixel opening OP1 or OP2 is greater than the overlapping area of the plurality of circuit patterns 108 with the sub-pixel opening OP3. For example, the overlapping area of the circuit patterns 108 of a plurality of sub-pixels with the sub-pixel opening OP3 may be zero or substantially equal to zero; the overlapping area of the plurality of circuit patterns 108 with the sub-pixel opening OP1 may be greater than the overlapping area of the plurality of circuit patterns 108 with the sub-pixel opening OP2.

In some embodiments, the sub-pixel circuit pc3 may be not disposed in the region R3 corresponding to the sub-pixel opening OP3, and may be arranged in at least one of the regions R1 and R2 corresponding to the sub-pixel openings OP1 and OP2 and/or at a position close thereto, for example. That is, the orthographic projection of the circuit pattern 108 of the sub-pixel circuit pc3 on the base substrate 100 may not overlap with the orthographic projection of the sub-pixel opening OP3 on the base substrate 100, and may overlap with and/or may be close to the orthographic projection of at least one of the sub-pixel openings OP1 and OP2 (e.g., the sub-pixel opening OP1) on the base substrate.

For example, as shown in FIG. 4A, the circuit patterns 108 overlapping with the sub-pixel opening OP1 may include at least part of the circuit pattern 108 of the sub-pixel circuit pc1, and may further include at least part of the circuit pattern of the sub-pixel pc3; and the circuit pattern 108 overlapping with the sub-pixel opening OP2 may include at least part of the circuit pattern 108 of the sub-pixel circuit pc2. It should be understood that the arrangement is only illustrative, and the present disclosure is not limited thereto, as long as the densities of the circuit patterns 108 in the respective regions are arranged in the above-mentioned manner or similar manner, and the flatness corresponding to each sub-pixel opening region can be improved. For example, a part of the sub-pixel circuit pc3 may also be arranged in the region R2, or a part of the sub-pixel circuit pc1 may also be arranged in the region R2, or a part of the sub-pixel circuit pc2 may also be arranged in the region R1.

In the above-mentioned embodiments, optimizing the arrangement of the respective layers of circuit patterns includes: arranging and partitioning circuit patterns in each layer (that is, concentratedly arranging a plurality of sub-pixel circuits in region(s) corresponding to a part of the sub-pixel openings) to adjust the densities of circuit patterns in regions overlapping with these sub-pixel openings, thereby improving the flatness of each sub-pixel opening region. In some other embodiments, optimizing the arrangement of the respective layers of circuit patterns may alternatively or additionally include: adjusting the uniformity of arrangement of circuit patterns in regions overlapping with the corresponding sub-pixel openings, so as to further improve the flatness of each sub-pixel opening region.

FIG. 3C is a schematic diagram illustrating a planar arrangement of a plurality of circuit patterns 103 of the conductive layer L1 and a plurality of sub-pixel openings OP1-OP3 according to some other embodiments of the present disclosure.

Referring to FIG. 3C, in some embodiments, the orthographic projection of a portion of the conductive layer L1 on the base substrate 100 overlaps with the orthographic projection of the sub-pixel opening OP1 on the base substrate 100, and the portion of the conductive layer L1 may include, for example, a plurality of wires having substantially equal line width and arranged at equal spacings. For example, the portion of the conductive layer L1 may include a plurality of wires (or may be referred to as wire patterns) 103t in the circuit patterns 103 of a plurality of sub-pixels, and the plurality of wires 103t may include signal wires such as gate lines, but the present disclosure does not limit the types of the plurality of wires. The line widths w1 of the plurality of wires 103t may be substantially the same, and the spacings dl between different adjacent wires 103t may be substantially the same; the line width w1 and the spacing d1 may be substantially the same as or different from each other. In the present disclosure, two or more numerical values, etc. being substantially the same includes the case where these numerical values are exactly the same, and also includes the case where the difference between each numerical value and the average value of the two or more numerical values is smaller than 5%˜20% of the average value, for example, the difference is smaller than 5%, 10%, 15% and 20% of the average value. That is, the difference between the line width of each of a plurality of wires and the average line width of the plurality of wires is smaller than 5%-20% of the average line width, and the difference between the spacing of every two adjacent wires and the average spacing of different adjacent wires is smaller than 5%-20% of the average spacing.

For example, a plurality of wires 103t may extend parallel to each other in a direction D1 and may be arranged in a direction D2, both of direction D1 and direction D2 are parallel to the main surface of the base substrate, and the directions D1 and D2 intersect with each other, for example, perpendicular to each other. The line width w1 of the wire 103t refers to the width of the wire 103t in the direction D2, and the spacing dl between adjacent wires 103t1 refers to the distance between two adjacent wires in the direction D2, that is, the width of the gap between adjacent wires in the direction D2.

In some embodiments, by arranging the plurality of wires 103t in the conductive layer L1 overlapping with the sub-pixel opening OP1 to have equal line width and equal spacing, the uniformity of distribution of circuit patterns in this region is improved, so that the flatness of the planarization layer located above the conductive layer L1 and corresponding to the sub-pixel opening region can be improved.

FIG. 4C is a schematic diagram illustrating a planar arrangement of circuit patterns of a second conductive layer and a plurality of sub-pixel openings according to some other embodiments of the present disclosure.

Referring to FIG. 2B and FIG. 4C, in some embodiments, in the conductive layer L2, the circuit patterns 108 of a plurality of sub-pixels include a first portion P1 and a second portion P2, and orthographic projections of the first portion P1 and the second portion P2 on the base substrate 100 overlap with orthographic projections of sub-pixel openings OP1 and OP2 on the base substrate, respectively. For example, the first portion PI may include at least part of the plurality of wires 108t1, and the second portion P2 may include at least part of the plurality of wires 108t2. The plurality of wires 108t1 and 108t2 may include conductive wires such as data signal lines connected to the source/drain electrodes of thin film transistors of a plurality of sub-pixels, for example, and the present disclosure does not limit the types of the plurality of wires.

In some embodiments, the plurality of wires 108t1 and 108t2 may extend substantially parallel to each other in the direction D2, and may be arranged in the direction D1. A plurality of wires 108t1 overlapping with the sub-pixel opening OP1 may have substantially the same line width w10 and may be spaced apart from each other by a spacing d10. In the case that the number of the plurality of wires 108t1 is greater than 2, the spacings d10 between adjacent wires 108t1 are substantially the same. The spacing d10 may be substantially the same as or different from the line width w10. A plurality of wires 108t2 overlapping with the sub-pixel opening OP2 may have substantially the same line width w20 and may be spaced apart from each other by a spacing d20. In the case that the number of the plurality of wires 108t2 is greater than 2, the spacings d20 between adjacent wires 108t2 are substantially the same. The spacing d20 may be substantially the same as or different from the line width w20. In some embodiments, the line widths w10 and w20 of the plurality of wires 108t1 and 108t2 may be the same as or different from each other, and the spacings d10 and d20 may be the same as or different from each other.

In some embodiments, when arranging a plurality of circuit patterns 108 of the conductive layer L2, a plurality of wires in the plurality of circuit patterns 108 may be classified, and wires with similar characteristics (e.g., having substantially the same line width and the same spacing) are concentratedly arranged below the same one pixel opening, thereby minimizing the influence of the circuit patterns on the flatness of the overlying planarization layer; in this way, the portion of the planarization layer located below each sub-pixel opening has a high flatness, so that the light-emitting devices of the plurality of sub-pixels can be formed on a flat surface, thereby improving the uniformity of light emission of the respective sub-pixels. For example, the plurality of wires 108t1 are wires of the first type, and the plurality of wires 108t2 are wires of the second type, and the line width w10 and spacing d10 of the plurality of wires 108t1 are different from the line width w20 and spacing d20 of the plurality of wires 108t2.

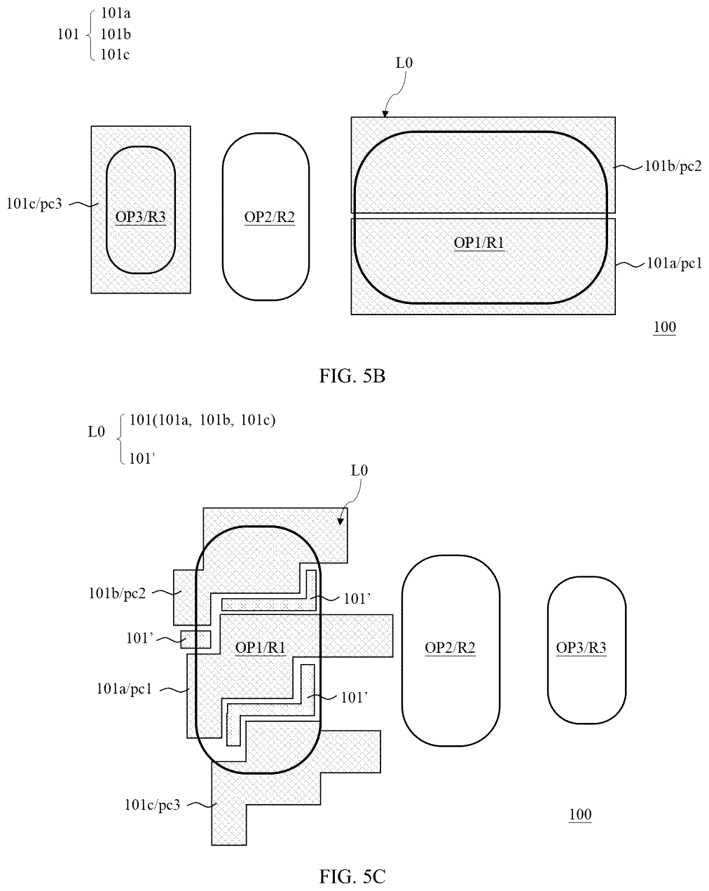

FIG. 5A is a schematic diagram illustrating a planar arrangement of an active material layer and sub-pixel openings in a display panel according to some embodiments of the present disclosure.

Referring to FIG. 5A, in some embodiments, in the active material layer L0, active patterns 101 of a plurality of sub-pixels may be concentratedly arranged in region(s) corresponding to sub-pixel opening(s) of a part of the sub-pixels (e.g., one or more sub-pixels), while the active patterns may be not arranged in region(s) corresponding to sub-pixel opening(s) of another part of the sub-pixels (e.g., one or more sub-pixels).

In some embodiments, the ratio of the overlapping area of active patterns of a plurality of sub-pixels with the second sub-pixel opening to the area of the second sub-pixel opening is smaller than the ratio of the overlapping area of the active patterns with the first sub-pixel opening to the area of the first sub-pixel opening, and may be smaller than or equal to the ratio of the overlapping area of the active patterns with the third sub-pixel opening to the area of the third sub-pixel opening. The ratio of the overlapping area of the active patterns with the third sub-pixel opening to the area of the third sub-pixel opening may be smaller than or greater than the ratio of the overlapping area of the active patterns with the first sub-pixel opening to the area of the first sub-pixel opening.

For example, the active patterns 101 of a plurality of sub-pixels may include an active pattern 101a of the sub-pixel circuit pc1, an active pattern 101b of the sub-pixel circuit pc2, and an active pattern 101c of the sub-pixel circuit pc3. The active pattern 101a of the sub-pixel circuit pc1 may be arranged in a region corresponding to the sub-pixel opening OP1, for example, in the region R1 and/or a region close to the region R1; and at least one of the active pattern 101b of the sub-pixel circuit pc2 and the active pattern 101c of the sub-pixel circuit pc3 may also be arranged in a region corresponding to the sub-pixel opening OP1. That is, the orthographic projection of the active pattern 101a on the base substrate 100 and the orthographic projection of at least one of the active patterns 101b and 101c on the base substrate 100 may overlap with the orthographic projection of the sub-pixel opening OP1 on the base substrate 100.

For example, as shown in FIG. 5A, the active patterns 101a, 101b, and 101c of the sub-pixel circuits pc1, pc2, and pc3 may be concentratedly arranged in a region corresponding to the sub-pixel opening OP1, such as in the region R1 and/or a region close to the region R1. In some embodiments, the active patterns may be substantially not arranged in regions R2 and R3 overlapping with sub-pixel openings OP2 and OP3.

In other words, in some embodiments, the orthographic projections of the active patterns 101b and 101c of the sub-pixel circuits pc2 and pc3 on the base substrate 100 may both be located outside the orthographic projections of the sub-pixel openings OP2 and OP3 on the base substrate 100, and the orthographic projections of the active patterns 101a, 101b and 101c of the sub-pixel circuits pc1, pc2 and pc3 on the base substrate 100 may each overlap with (e.g., partially overlap with) the orthographic projection of the sub-pixel opening OP1 on the base substrate 100.

In this embodiment, as shown in FIG. 5A, the density of the active patterns 101 arranged in the region R1 is greater than the densities of the active patterns 101 arranged in the regions R2 and R3; and the density of the active patterns 101 in the region R2 and the density of the active patterns in the region R3 may be the same as each other, for example, both are 0. That is to say, the ratio of the overlapping area of the active patterns 101 of a plurality of sub-pixels with the sub-pixel opening OP1 to the area of the sub-pixel opening OP1 is greater than the ratio of the overlapping area of the active patterns 101 with the sub-pixel opening OP2 to the area of the sub-pixel opening OP2, and is greater than the ratio of the overlapping area of the active patterns 101 with the sub-pixel opening OP3 to the area of the sub-pixel opening OP3. The ratio of the overlapping area of the active patterns 101 with the sub-pixel opening OP2 to the area of the sub-pixel opening OP2 and the ratio of the overlapping area of the active patterns 101 with the sub-pixel opening OP3 to the area of the sub-pixel opening OP3 may be the same, for example, both are 0.

For example, the overlapping area of the active patterns 101 with the sub-pixel opening OP1 is greater than the overlapping area of the active patterns 101 with the sub-pixel opening OP2 or OP3. The overlapping area of the active patterns 101 with at least one of the sub-pixel openings OP2 and OP3 may be zero.

FIG. 5B is a schematic diagram illustrating a planar arrangement of active patterns of an active material layer and sub-pixel openings according to some other embodiments of the present disclosure.

Referring to FIG. 5B, in some embodiments, in the active material layer L0 of the pixel circuit layer, the active patterns may be not disposed in a region corresponding to a part of the sub-pixel openings, an entire active pattern may be disposed in a region corresponding to part of the sub-pixel openings, while a plurality of active patterns may be arranged in a region corresponding to another part of the sub-pixel openings. For example, the active pattern may be not provided in a region (region R2 and/or a region close thereto) corresponding to the sub-pixel opening OP2, a plurality of active patterns may be provided in a region (region R1 and/or a region close thereto) corresponding to the sub-pixel opening OP1, and the plurality of active patterns may be spaced apart from each other; an entire active pattern may be provided in a region (region R3 and/or a region close thereto) corresponding to the sub-pixel opening OP3.

For example, at least part of the active pattern 101a of the sub-pixel circuit pc1 may be located in the region R1, and the orthographic projection of the active pattern 101a on the base substrate 100 overlaps with the orthographic projection of the sub-pixel opening OP1 on the base substrate 100; the orthographic projection of at least one of the active pattern 101b of the sub-pixel circuit pc2 and the active pattern 101c of the sub-pixel circuit pc3 on the base substrate 100 may overlap with the orthographic projection of the sub-pixel opening 101 on the base substrate.

For example, the orthographic projection of the active pattern 101b of the sub-pixel circuit pc2 on the base substrate 100 may be located outside the orthographic projection of the sub-pixel opening OP2 on the base substrate 100, and the orthographic projections of the active pattern 101b of the sub-pixel circuit pc2 and the active pattern 101a of the sub-pixel circuit pc1 on the base substrate 100 may both overlap with the orthographic projection of the sub-pixel opening OP1 on the base substrate 100; the active patterns 101a and 101b are spaced apart from each other. The orthographic projection of the active pattern 101c of the sub-pixel circuit pc3 on the base substrate 100 and the orthographic projection of the sub-pixel opening OP3 on the base substrate 100 may overlap with each other, and the orthographic projection of the sub-pixel opening OP3 on the base substrate 100 may be located within the range of orthographic projection of the active pattern 101c on the base substrate 100.

In this embodiment, as shown in FIG. 5B, the density of the active patterns 101 arranged in the region R3 of the pixel circuit layer may be greater than the density of the active patterns 101 in the region R1, and the density of the active patterns 101 in the region R1 may be greater than the density of the active patterns 101 in the region R2. That is to say, the ratio (i.e., 1) of the overlapping area of active patterns 101 of a plurality of sub-pixels with the sub-pixel opening OP3 to the area of the sub-pixel opening OP3 is greater than the ratio of the overlapping area of the active patterns 101 with the sub-pixel opening OP1 to the area of the sub-pixel opening OP1, and the ratio of the overlapping area of the active patterns 101 with the sub-pixel opening OP1 to the area of the sub-pixel opening OP1 is greater than the ratio (e.g., 0) of the overlapping area of the active patterns 101 with the sub-pixel opening OP2 to the area of the sub-pixel opening OP2.

As shown in FIG. 5A and FIG. 5B, in some embodiments, the sizes of sub-pixel openings OP1, OP2 and OP3 are different from each other, for example, the area of the sub-pixel opening OP1 is greater than the area of the sub-pixel opening OP2, and the area of the sub-pixel opening OP2 is greater than the area of the sub-pixel opening OP3. In some embodiments, there may be free of active pattern or there may be an entire active pattern arranged in the region R3 corresponding to the sub-pixel opening OP3 with a smaller area, a plurality of active patterns may be arranged in the region R1 corresponding to the sub-pixel opening OP1 with a larger area and the plurality of active patterns are spaced apart from each other; while the region R2 corresponding to the sub-pixel opening OP2 with an intermediate area (i.e., an area at an intermediate level compared with other sub-pixel openings) may be free of active pattern. However, the present disclosure is not limited thereto.

For example, the overlapping area of the active patterns 101 with the sub-pixel opening OP2 may be less than the overlapping area of the active patterns 101 with the sub-pixel opening OP1 or the overlapping area of the active patterns 101 with the sub-pixel opening OP3; the overlapping area of the active patterns 101 with the sub-pixel opening OP1 may be greater than the overlapping area of the active patterns 101 with the sub-pixel opening OP3. For example, the overlapping area of the active patterns 101 with the sub-pixel opening OP3 may be equal to the area of the sub-pixel opening OP3.

FIG. 6 is a schematic plan view illustrating a pixel circuit pattern and a sub-pixel opening according to some embodiments of the present disclosure.

In some embodiments, at least one of the conductive layer L1, the conductive layer L2, the active material layer L0 and/or other pattern layers includes a block pattern, and the orthographic projection of a portion of the block pattern on the base substrate 100 overlaps with the orthographic projection of a sub-pixel opening on the base substrate 100. In some embodiments, the block pattern is designed to be linear and uniform, that is, a portion of the block pattern overlapping with the sub-pixel opening is divided into a plurality of strip patterns, and these plurality of strip patterns can be uniformly arranged, so that the flatness of a region corresponding to this sub-pixel opening can be improved. The block pattern may include, for example, a square block pattern, a rectangular block pattern, a circular block pattern, an elliptical block pattern, or any other type of block patterns. In the present disclosure, a block pattern refers to a pattern in which the ratio of its size (e.g., width, length, etc.) along a first direction to its size (e.g., width, length, etc.) along a second direction is in the range of 1:1 to 5:1 or 1:1 to 6:1, and the second direction is substantially perpendicular to the first direction; a strip pattern refers to a pattern in which the ratio of its size (e.g., length) along the first direction to its size (e.g., width) along the second direction is greater than or equal to 10:1.

In some embodiments, in the case that the overlapping area of the block pattern with the sub-pixel opening accounts for more than 10% of the area of the sub-pixel opening, the block pattern has a great influence on the flatness of a region corresponding to the sub-pixel opening. In this case, the block pattern is designed to be linear and uniform to reduce the ratio of the overlapping area of the block pattern with the sub-pixel opening to the area of the sub-pixel opening to be smaller than 10%, for example, smaller than 8%, or smaller than 5%, thereby reducing the influence of the block pattern on the flatness of the region corresponding to the sub-pixel opening, and improving the flatness of a region of the planarization layer corresponding to the sub-pixel opening.

In some embodiments, the block pattern may include at least one of the following: one or more gate patterns, one or more source/drain electrode patterns, one or more transfer electrode patterns, one or more active patterns or other types of patterns. The block pattern may be a circuit pattern connected to a gate scanning signal, a data signal, a detection signal, a compensation signal, a grounding signal or any other types of signals, and the present disclosure does not limit the specific functions of the block pattern and the types of signals connected thereto.

FIG. 6 schematically illustrates positional relationships between a plurality of patterns of a pattern layer L in a pixel circuit layer 110 and a sub-pixel opening OP. The sub-pixel opening OP may be any of the above-mentioned sub-pixel openings OP1, OP2 and OP3, and the pattern layer L may be any of the active material layer L0, the conductive layer L1 and the conductive layer L2.

Referring to FIG. 6, in some embodiments, the orthographic projections of a plurality of patterns ap and bp located at the pattern layer L on the base substrate 100 overlap (e.g., partially overlap) with the orthographic projection of the sub-pixel opening OP on the base substrate 100. In some embodiments, the pattern bp is a block pattern; in the present disclosure, a block pattern may include a whole continuous pattern, and may also include a pattern block with a hollowed-out portion therein. The pattern bp shown in FIG. 6 is a block pattern which has been designed to be linear and uniform. For example, the pattern bp may include a body portion bpl and an overlapping portion bp2 connected to each other; the overlapping portion bp2 is a portion that at least partially overlaps with the sub-pixel opening OP. In some embodiments, the body portion bp1 is in a continuous block shape, and the overlapping portion bp2 includes a plurality of strip portions t1 which are spaced apart from each other, extend substantially parallel to each other in the direction D2 and are arranged in the direction D1. That is, the pattern bp has a hollowed-out portion th1 between a plurality of strip portions t1. The plurality of strip portions t1 are connected to the body portion bp1, and may be electrically connected with each other through the body portion bp1. In some embodiments, the overlapping portion bp2 may further include a strip portion t2, and the extending direction of the strip portion t2 may be different from (e.g., perpendicular to) that of the strip portion t1. The strip portion t2 is connected to a plurality of strip portions t1.

In some embodiments, the orthographic projection of the continuous block-shaped body portion bpl on the base substrate 100 may be located outside the orthographic projection of the sub-pixel opening OP on the base substrate 100, and the orthographic projection of at least part of the plurality of strip portions t1 on the base substrate 100 overlaps with the orthographic projection of the sub-pixel opening OP on the base substrate 100. The orthographic projection of at least part of the strip portion t2 on the base substrate 100 may overlap with the orthographic projection of the sub-pixel opening OP on the base substrate 100.

In some embodiments, at least parts of the plurality of strip portions t1 overlapping with the sub-pixel opening OP have substantially the same width w3; the spacings d3 between adjacent strip portions t1 may be substantially the same, that is, a plurality of hollowed-out portions th1 overlapping with the sub-pixel opening OP may have substantially the same width.

In some embodiments, other patterns ap overlapping with the sub-pixel opening OP may include a plurality of strip patterns, block patterns with smaller areas, and/or patterns of other shapes that are dispersed from each other.

In some embodiments, for example, the block pattern 103p of the conductive layer L1 shown in FIG. 3B and the block pattern 108p of the conductive layer L2 shown in FIG. 4B can be designed to be linear and uniform as shown in FIG. 6, and the portions of the block patterns 103p and 108p overlapping with the corresponding sub-pixel openings can be patterned to have a plurality of strips.

In this embodiment, the large-area block pattern in the region corresponding to the sub-pixel opening is arranged in a linear and uniform way, for example, a portion thereof in the region corresponding to the sub-pixel opening is divided into a plurality of strip patterns, so as to avoid influencing the flatness of the sub-pixel opening region due to a large step difference of the planarization layer located above the large-area block pattern relative to the planarization layer located above other patterns; such arrangement enables the patterns in a region corresponding to the sub-pixel opening to be evenly distributed, thereby improving the flatness in this region.

In some embodiments, dummy patterns may be further arranged in the respective pattern layers of the pixel circuit layer. The dummy patterns may be arranged in a gap region between adjacent circuit patterns and/or adjacent active patterns, and may be arranged in a region corresponding to one or more sub-pixel openings. For example, in each pattern layer, after the pixel circuit patterns are concentratedly arranged in region(s) corresponding to one or more sub-pixel openings, dummy patterns may be further arranged in a gap region of the pixel circuit patterns to adjust the density and/or uniformity of the overall pattern in the region overlapping with the corresponding sub-pixel opening, so that a plurality of patterns (i.e., the combination of pixel circuit patterns and dummy patterns) in the region corresponding to the sub-pixel openings has an appropriate density and/or uniformity (e.g., they are uniformly distributed in the region) as a whole; in this way, the flatness of the region corresponding to the sub-pixel opening can be improved, for example, the planarization layer in the region has a high flatness and provides a flat surface for the light-emitting device, thereby improving the uniformity of light emission of the light-emitting device. In some embodiments, before providing the dummy patterns, the pixel circuit patterns can be arranged uniformly, for example, (e.g., the line widths and spacings of the wires) of the pixel circuit patterns overlapping with the same sub-pixel opening can be set to have the same size and spacing. In some embodiments, the dummy patterns may be formed from the same material layer through the same patterning process as the pixel circuit patterns (e.g., conductive patterns, active patterns, etc.) in the same layer. In the present disclosure, the dummy pattern is electrically isolated from other pixel circuit patterns. For example, the dummy pattern may be electrically floating, that is, the dummy pattern is not connected to any other conductive member and/or voltage source; alternatively, the dummy pattern may also be connected to a fixed potential, for example, may be grounded or may be connected to a direct current (DC) signal terminal. In some embodiments, providing the dummy patterns can not only improve the flatness of regions corresponding to the sub-pixel openings, but also shield signal crosstalk between adjacent circuit patterns. For example, after the pixel circuit patterns are concentratedly arranged in the region(s) corresponding to one or more sub-pixel openings, the circuit patterns of different sub-pixel circuits may be close to each other, and dummy pattern may be arranged between the circuit patterns of different sub-pixel circuits, thus effectively avoiding signal crosstalk between adjacent circuit patterns (e.g., between circuit patterns of different sub-pixel circuits), and further improving the reliability of the devices.

FIG. 3D is a schematic plan view of a conductive layer L1 and a plurality of sub-pixel openings OP1-OP3 according to some embodiments of the present disclosure. The conductive layer L1 shown in FIG. 3D is, for example, added with a dummy pattern based on the conductive layer L1 shown in FIG. 3B.

For example, as shown in FIG. 3D, the conductive layer L1 includes circuit patterns 103 of a plurality of sub-pixels, and one or more dummy patterns (or may be referred to as first dummy patterns) 103′ which are arranged in gap regions of the circuit patterns 103 (i.e., gaps between adjacent circuit patterns), and the orthographic projection of the dummy patterns 103′ on the base substrate 100 may overlap with the orthographic projection of at least one of the sub-pixel openings OP1 to OP3 (e.g., the sub-pixel opening OP1) on the base substrate 100. The dummy pattern 103′ is configured to at least partially fill the gaps of the circuit patterns 103 overlapping with the sub-pixel opening to adjust the density and/or uniformity of the whole pattern (i.e., the combination of the circuit pattern 103 and the dummy pattern 103′) in the region RI overlapping with the corresponding sub-pixel opening, thereby improving the flatness of the planarization layer located above the region. In some embodiments, the shape of the dummy patterns 103′ may include a strip shape, a block shape or any suitable shapes, and the sizes of different dummy patterns 103′ may be the same as or different from each other. For example, the dummy pattern 103′ may include a strip-shaped dummy pattern 103a′ and a block-shaped dummy pattern 103b′, wherein the strip-shaped dummy pattern 103a′ may have a size as same as or different from that of its adjacent strip-shaped circuit pattern (e.g., wire pattern), and the block-shaped dummy pattern 103b′ may also have a size as same as or different from that of its adjacent block-shaped circuit pattern. The dummy pattern 103′ may be arranged in any gap of a plurality of circuit patterns 103, for example, it may be arranged in a gap region of the circuit pattern 103 of the same sub-pixel circuit and/or in a gap region of circuit patterns 103 of different sub-pixel circuits. The present disclosure does not limit the shape, size and specific position of the dummy pattern 103′, as long as at least part of the dummy pattern 103′ is arranged in the region corresponding to the sub-pixel opening (e.g., at least one of the regions R1-R3) and the flatness of the region is improved.

FIG. 3E is a schematic plan view illustrating a conductive layer L1 and a plurality of sub-pixel openings OP1-OP3 according to some other embodiments of the present disclosure.

Referring to FIG. 3E, in some embodiments, in the conductive layer L1, the circuit patterns 103 overlapping with the sub-pixel opening OP1 may include a plurality of wire patterns 103t, and the dummy pattern 103a′is arranged in gap regions of the plurality of wire patterns 103t. For example, the dummy pattern 103a′ may be arranged in a strip shape, i.e., substantially the same shape as the wire pattern 103t. A plurality of wire patterns 103t and dummy patterns 103a′ may extend substantially parallel to each other in the direction D1 and may be arranged in the direction D2. The width w1 of the wire pattern 103t and the width w2 of the dummy pattern 103a′ may be substantially the same as each other; the spacings d1′ between adjacent patterns among the plurality of wire patterns 103t and dummy patterns 103a′ may be substantially the same. For example, the dummy patterns 103a′ and the wire patterns 103t may be alternately arranged along the direction D2, that is, each dummy pattern 103a′ may be arranged between two adjacent wire patterns 103t, and the spacings between the dummy pattern 103a′ and the adjacent wire patterns 103t may be substantially the same. However, the present disclosure is not limited thereto. In some other embodiments, the plurality of wire patterns 103t and dummy patterns 103a′ may not be arranged alternately, and any other suitable arrangement mode may be adopted, as long as the overall pattern constituted by the circuit patterns and dummy patterns in the region R1 corresponding to the sub-pixel opening OP1 has a suitable density and uniform arrangement and enables the planarization layer located above the region R1 to have a high flatness.

In the embodiment shown in FIG. 3D and FIG. 3E, the dummy patterns 103′ and the circuit patterns 103 are arranged in the same layer and spaced apart from each other, and can be formed from the same conductive material layer by the same patterning process, thereby simplifying the manufacturing process. In some embodiments, the dummy pattern 103′ is arranged in a region (e.g., the region R1 and a region close thereto) which corresponds to the sub-pixel opening and has been provided with a circuit pattern 103, while the dummy pattern is not arranged in a region (e.g., the regions R2, R3 and a region close thereto) which corresponds to a sub-pixel opening but is not provided with a circuit pattern 103.

FIG. 4D and FIG. 4E are schematic plan views illustrating a conductive layer L2 and a plurality of sub-pixel openings OP1-OP3 according to some other embodiments of the present disclosure.

Referring to FIG. 4D, in some embodiments, the conductive layer L2 includes circuit patterns 108 of a plurality of sub-pixels, and may further include one or more dummy patterns (or may be referred to as second dummy patterns) 108′ which are arranged in gap regions of a plurality of circuit patterns 108, and the orthographic projection of at least part of the plurality of dummy patterns 108′ on the base substrate 100 may overlap with the orthographic projection of at least one of the sub-pixel openings OP1-OP3 on the base substrate. For example, the dummy pattern 108′ may be arranged in regions (regions R1 and R2 and/or regions close thereto) corresponding to the sub-pixel openings OP1 and OP2. The dummy pattern 108′ may be in a strip shape, a block shape or any suitable shapes, and the size of the dummy pattern 108′ may be as same as or different from that of the adjacent circuit pattern 108. The present disclosure does not limit the shape, size and specific position of the dummy pattern 108′, as long as at least part of the dummy pattern 108′ is arranged in a region corresponding to the sub-pixel opening (e.g., at least one of the regions R1-R3) and the flatness of the region can be improved. In some embodiments, if the circuit pattern 108 is not provided in a region corresponding to the sub-pixel opening, the dummy pattern is not provided in this region, either. For example, the circuit pattern 108 is not provided in the region R3 corresponding to the sub-pixel opening OP3, the dummy pattern 108′ is not provided in this region, either.

Referring to FIG. 4E, in some embodiments, in the conductive layer L2, the dummy patterns 108′ may be strip-shaped and have a line width and a spacing as same as those of the wire patterns in the adjacent circuit patterns 108. For example, the circuit pattern 108 may include a plurality of wire patterns 108t1 and 108t2, and the dummy pattern 108′ may include strip-shaped dummy patterns 108a′ and 108b′; the dummy patterns 108a′ and 108b′ may also be referred to as dummy wire patterns.

For example, at least parts of the wire patterns 108t1 and 108t2 are located in regions R1 and R2 corresponding to the sub-pixel openings OP1 and OP2, respectively, and at least parts of the dummy patterns 108a′ and 108b′ are also located in regions R1 and R2 corresponding to the sub-pixel openings OP1 and OP2, respectively. One or more dummy patterns 108a′ may be adjacent to the wire pattern 108t1, for example, arranged in gap region(s) of a plurality of wire patterns 108t1, and the line width w10′ of the dummy pattern 108a′ and the line width w10 of the wire pattern 108t1 may be substantially the same as each other. In the region R1, the spacings d10′ between adjacent patterns among the dummy patterns 108a′ and the wire patterns 108t1 may be substantially the same. One or more dummy patterns 108b′ may be adjacent to the wire patterns 108t2, for example, arranged in gap region(s) of a plurality of wire patterns 108t2, and the line width w20′ of the dummy pattern 108b′ and the line width w20 of the wire pattern 108t2 may be substantially the same as each other. In the region R2, the spacings d20′ between adjacent patterns among the dummy patterns 108b′ and the wire patterns 108t2 may be substantially the same. It should be understood that the number and specific positions of the wire patterns and dummy patterns in the regions R1 and R2 shown in the drawing are only illustrative, and the present disclosure is not limited thereto. More or less wire patterns and/or dummy patterns may be arranged in these regions. For example, in a plurality of wire patterns, more than one dummy pattern may be arranged in the gap regions between some adjacent wire patterns, and no dummy pattern may be arranged in the gap regions between some other adjacent wire patterns; the dummy patterns and wire patterns in the regions R1 and R2 can be arranged in any suitable manner, as long as the planarization layer overlying the regions has a high flatness.

In some embodiments, in the conductive layer L2, the dummy pattern 108′ and the circuit pattern 108 are arranged in the same layer and spaced apart from each other, and may be formed from the same conductive material layer through the same patterning process, thereby simplifying the manufacturing process. In some embodiments, the dummy pattern 108′ may be arranged in one or more regions (e.g., regions R1 and R2 and regions close thereto) which correspond to the sub-pixel opening(s) and have been provided with the circuit pattern 108, while the dummy pattern may be not arranged in region(s) (e.g., the region R3 and a region close thereto) which correspond to the sub-pixel opening(s) but is provided with the circuit pattern 108.

FIG. 5C is a schematic plan view illustrating an active material layer L0 and a plurality of sub-pixel openings OP1-OP3 according to some embodiments of the present disclosure.

Referring to FIG. 5C, in some embodiments, the active material layer L0 includes active patterns 101 of a plurality of sub-pixels, and may further include one or more dummy patterns (or also referred to as third dummy patterns) 101′ which are arranged in gap regions of the active patterns 101 of the plurality of sub-pixels. At least part of the dummy patterns 101′ may be arranged in a region of the active material layer L0 corresponding to at least one of a plurality of sub-pixel openings. That is, the orthographic projection of at least part of the dummy pattern 101′ on the base substrate 100 may overlap with the orthographic projection of one or more of a plurality of sub-pixel openings OP1-OP3 on the base substrate 100. For example, as shown in FIG. 5C, the dummy pattern 101′ may be arranged in a region R1 corresponding to the sub-pixel opening OP1 and/or in a region adjacent to the region R1, and may be located in a gap between adjacent active patterns 101 and spaced apart from the active patterns 101. The shape of the dummy pattern 101′ may include a strip shape, a block shape, an irregular shape or any suitable shapes. The size of the dummy pattern 101′ may be as same as or different from that of the adjacent active patterns. The present disclosure does not limit the shape, size and specific position of the dummy pattern 101′, as long as at least part of the dummy pattern 101′ is arranged in a region corresponding to the sub-pixel opening (e.g., one or more of regions R1-R3) to adjust the density and/or uniformity of the overall pattern of the active material layer in this region, thereby improving the flatness of the planarization layer located above this region.

The dummy pattern 101′ and the active pattern 103 are arranged in the same layer and spaced apart from each other, and can be formed from the same active material through the same patterning process, thereby simplifying the manufacturing process. In some embodiments, the dummy pattern may be not provided in a region (e.g., regions R2 and R3 shown in FIG. 5C) which correspond to a sub-pixel opening and is not provided with an active pattern, but the present disclosure is not limited thereto.

In some other embodiments, for example, in the active material layer L0 shown in FIG. 5B, a dummy pattern may be provided between adjacent active patterns 101a and 101b in the region R1 corresponding to the sub-pixel opening OP1, and the dummy pattern may be not provided in the region R2 where no active pattern is provided and the region R3 where a whole active pattern is provided.

It should be understood that in the embodiment of the present disclosure, each layer in the pixel circuit layer may or may not be provided with a dummy pattern depending on the arrangement of the pixel circuit patterns in this layer. In the case where a dummy pattern is included in the pixel circuit layer, the dummy pattern may be arranged in one or more layers of the pixel circuit layer, such as one or more of the active material layer L0, the first conductive layer L1, and the second conductive layer L2. That is, in some embodiments, the display panel may include one or more of the first, second and third dummy patterns described above.

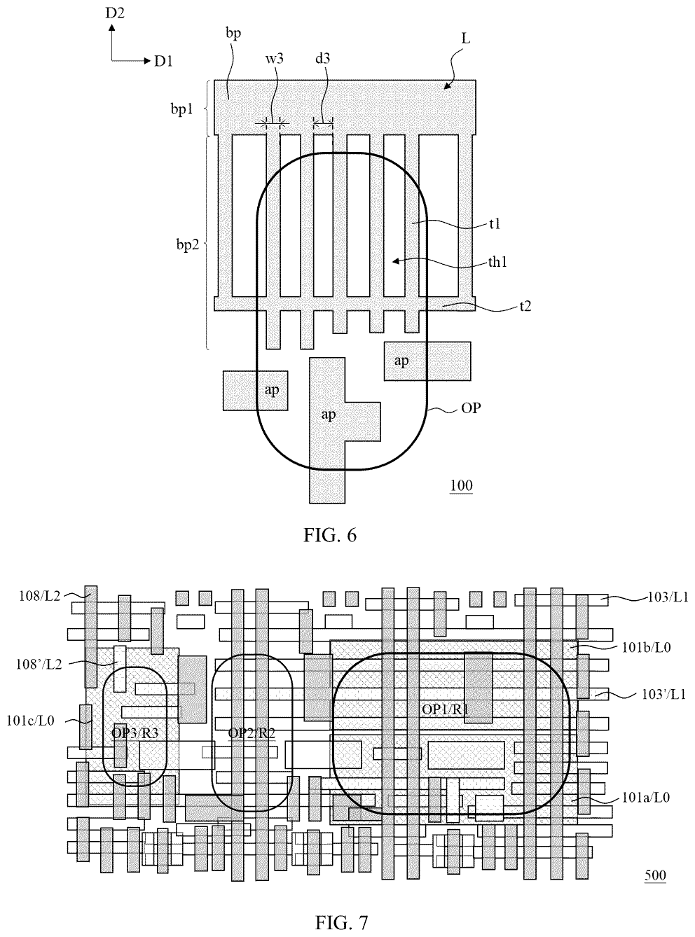

FIG. 7 is a schematic diagram illustrating a planar arrangement of a plurality of staked layers in a pixel circuit layer and a plurality of sub-pixel openings of a display panel according to some embodiments of the present disclosure. The arrangement of the sub-pixel openings OP1-OP3 and the active material layer L0 shown in FIG. 7 is similar to that shown in FIG. 5B, and the arrangement of the active patterns of the active material layer L0 can refer to what has been described above with respect to FIG. 5B, which is not repeated here.

Referring to FIG. 7, in some embodiments, the sub-pixel openings OP1-OP3 of different sub-pixels have different sizes and/or shapes, and the arrangement of various layers of patterns (e.g., the active material layer L0, the conductive layer L1, the conductive layer L2) of the pixel circuit layer can be optimized according to the characteristics of different sub-pixels, so as to improve the flatness of the planarization layer in the regions corresponding to the sub-pixel opening OP1-OP3; in this way, the light-emitting devices can be formed on a flat surface, and the uniformity of light emission of the light-emitting regions of the respective sub-pixels can be improved.

In some embodiments, the density of circuit patterns arranged in a region of the pixel circuit layer corresponding to a sub-pixel opening with a larger size (e.g., sub-pixel opening OP1) may be greater than the densities of circuit patterns arranged in regions corresponding to other sub-pixel openings with smaller sizes (e.g., sub-pixel opening OP2 or OP3). In some embodiments, the densities of circuit patterns in regions R1 to R3 of the pixel circuit layer may be substantially positively correlated with the sizes of sub-pixel openings OP1-OP3 corresponding to these regions. That is, the larger the size of the sub-pixel opening is, the greater the density of the circuit patterns arranged in the region of the pixel circuit layer corresponding to the sub-pixel opening will be. However, the present disclosure is not limited thereto. Herein, the density of circuit patterns in a certain region of the pixel circuit layer may include the density of the first circuit patterns of the first conductive layer in this region, the density of the second circuit patterns of the second conductive layer in this region, or the sum of the density of the first circuit patterns and the density of the second circuit patterns.

In some embodiments, dummy patterns may be arranged in one or more of the active material layer L0, the conductive layer L1, and the conductive layer L2; at least part of the dummy patterns of the respective layers may be located in region(s) corresponding to the sub-pixel opening(s), for example, in one or more of the regions R1-R3 of the pixel circuit layer, and may extend to regions other than these regions. In some other embodiments, the dummy pattern may also be arranged in other regions that do not overlap with the sub-pixel openings, so as to improve the flatness of the planarization layer located above these regions, for example, to improve the overall flatness of the planarization layer.

For example, as shown in FIG. 7, a dummy pattern 103′ located in the gap region of the circuit patterns 103 is provided in the conductive layer L1, and a dummy pattern 108′ located in the gap region of the circuit patterns 108 is provided in the conductive layer L2. The dummy patterns shown in the drawing are only illustrative, and the present disclosure does not limit the number, size and specific positions of the dummy patterns. In some embodiments, a dummy pattern may also be provided in the gap region of the active patterns of the active material layer.

It should be understood that, the above embodiment is described with reference to the case where the pixel circuit layer 110 includes an active material layer L0, a conductive layer L1, and a conductive layer L2 by way of example, and the type and number of pattern layers included in the pixel circuit layer are not limited thereto.

For example, the pixel circuit layer includes a plurality of pattern layers, and a first pattern layer among the plurality of pattern layers includes a plurality of first patterns of the plurality of sub-pixels, and the orthographic projection of the plurality of first patterns on the base substrate overlaps with the orthographic projection of at least one of the first sub-pixel opening, the second sub-pixel opening and the third sub-pixel opening on the base substrate; the overlapping area of the plurality of first patterns with the first sub-pixel opening is greater than the overlapping area of the plurality of first patterns with the second sub-pixel opening or the overlapping area of the plurality of first patterns with the third sub-pixel opening. For example, the overlapping area of the plurality of first patterns with at least one of the second sub-pixel opening and the third sub-pixel opening is zero. For example, the plurality of pattern layers may include one or more gate layers, one or more source/drain electrode metal layers, one or more active material layers, one or more transfer layers including transfer electrodes, and/or other pattern layers. For example, the plurality of first patterns include circuit patterns of the plurality of sub-pixels connected to the same signal (e.g., gate scanning signal, data signal, compensation signal, detection signal, etc.). The first pattern is, for example, the circuit pattern 103 or 108, but may also be a pixel circuit pattern of another material layer.

In some embodiments, the plurality of pattern layers further include a second pattern layer located on a side of the first pattern layer close to or away from the light-emitting device, and the second pattern layer includes a plurality of second patterns of the plurality of sub-pixels, and the overlapping area of the plurality of second patterns with the first sub-pixel opening is greater than the overlapping area of the plurality of second patterns with the second sub-pixel opening or the third sub-pixel opening. For example, the overlapping area of the plurality of second patterns with the second sub-pixel opening is zero. For example, the overlapping area of the plurality of second patterns with the third sub-pixel opening is zero or equal to the area of the third sub-pixel opening. The second pattern is, for example, an active pattern located at the active material layer. In some embodiments, each pattern layer of the plurality of pattern layers may be arranged in one of the arrangement modes of the various layers described with reference to the above embodiments, thereby improving the flatness of the planarization layer in the region corresponding to each sub-pixel opening.

In some embodiments, the patterns (i.e., circuit patterns/active patterns, etc.) in each layer of the pixel circuit layer 110 are concentratedly arranged in a region corresponding to part of the sub-pixel openings, so that pixel circuit patterns are arranged at a higher density in this region, while no pixel circuit pattern is arranged in a region corresponding to another part of the sub-pixel openings, thereby minimizing the influence of the pixel circuit patterns on the flatness of the surface of the planarization layer in the regions corresponding to the sub-pixel openings at a side away from the base substrate, and ensuring that at least a portion of the planarization layer corresponding to each sub-pixel opening has a relatively high flatness. In some embodiments, the arrangement of each layer of patterns of the pixel circuit layer 110 is optimized, so that each layer of patterns has an appropriate density and/or uniformity in the regions overlapping with the sub-pixel openings, thereby improving the flatness of the planarization layer in the regions corresponding to the sub-pixel openings. In some embodiments, since the pixel circuit patterns arranged in the regions corresponding to various sub-pixel openings have different densities, there may be a certain step difference between the portions of the planarization layer corresponding to different sub-pixel openings.

Referring back to FIG. 2B, for example, in some embodiments, the planarization layer 111 is disposed on a side of the pixel circuit layer 110 away from the base substrate 100 (i.e., over the pixel circuit layer 110 as illustrated in the drawing), and is located between the pixel circuit layer 110 and the pixel defining layer 112/light-emitting device layer 116; the planarization layer 111 is configured to provide a flat surface for components overlying the planarization layer 111, so that the light-emitting device layer 116 is arranged on a flat surface, for example, at least a portion of the light-emitting device layer 116 located in the sub-pixel openings is formed on the flat surface, thereby ensuring the uniformity of light emission of light-emitting regions in various sub-pixels.

In some embodiments, the densities of the pixel circuit patterns arranged in the regions R1-R3 of the pixel circuit layer 110 are different from each other, for example, the overall density of the pixel circuit patterns in the region RI of the pixel circuit layer 110 is greater than the overall density of the pixel circuit patterns in the region R2, and the overall density of the pixel circuit patterns in the region R2 is greater than the overall density of the pixel circuit patterns in the region R3. In this way, there may be a certain step difference between various portions of the planarization layer 111 corresponding to the regions R1-R3. In the present disclosure, the overall density of the pixel circuit patterns in a certain region of the pixel circuit layer refers to the sum of the densities of the patterns in various layers of this region.

For example, the planarization layer 111 includes a flat portion 111a, a flat portion 111b, and a flat portion 111c corresponding to regions R1, R2, and R3 of the pixel circuit layer and sub-pixel openings OP1, OP2, and OP3, respectively. The flat portion 111a, the flat portion 111b, and the flat portion 111c may be referred to as a first flat portion, a second flat portion, and a third flat portion, respectively. The flat portions 111a-111c respectively provide flat surfaces with high flatness for the light-emitting devices in the sub-pixel opening regions OP1-OP3. The orthographic projections of the region R1 and the sub-pixel opening OP1 on the base substrate 100 may be located within the range of orthographic projection of the flat portion 111a on the base substrate 100; the orthographic projections of the region R2 and the sub-pixel opening OP2 on the base substrate 100 may be located within the range of orthographic projection of the flat portion 111b on the base substrate 100; the orthographic projections of the region R3 and the sub-pixel opening OP3 on the base substrate 100 may be located within the range of orthographic projection of the flat portion 111c on the base substrate 100.

In some embodiments, there may be a step difference between different flat portions of the planarization layer 111 (e.g., at least two of the flat portions 111a to 111c); that is, surfaces of the flat portions at a side away from the base substrate may be located at different level heights relative to the main surface of the base substrate 100, for example. In the present disclosure, the level height of each flat portion relative to the main surface of the base substrate refers to the average height of the flat portion relative to the main surface of the base substrate, that is, the average height of various positions of the flat portion relative to the main surface of the base substrate in the direction perpendicular to the main surface of the base substrate. For example, the flat portion 111a, the flat portion 111b, and the flat portion 111c respectively have a flat surface S1, a flat surface S2, and a flat surface S3 which are away from the base substrate 100 and close to the pixel defining layer 112 and the light-emitting device layer 116. The flat surface S1, the flat surface S2, and the flat surface S3 may also be referred to as a first flat surface, a second flat surface, and a third flat surface, respectively. At least two of the flat surfaces S1-S3 may have different distances from the main surface of the base substrate 100. In some embodiments, the heights of the flat surfaces S1-S3 relative to the main surface of the base substrate 100 may be substantially positively correlated with the overall densities of pixel circuit patterns and/or dummy patterns in the corresponding regions R1-R3 of the pixel circuit layer 110.

For example, the overall pattern density in the region R1 of the pixel circuit layer 110 may be greater than the overall pattern density in the region R2 or R3, and the overall pattern density in the region R2 may be greater than the overall pattern density in the region R3. The distance H1 between the flat surface S1 and the main surface of the base substrate 100 may be greater than the distance H2 between the flat surface S2 and the main surface of the base substrate 100, and the distance H2 between the flat surface S2 and the main surface of the base substrate 100 may be greater than the distance H3 between the flat surface S3 and the main surface of the base substrate 100. Here, the distance between each flat surface and the main surface of the base substrate is the average value of the distances between various positions of the flat surface and the main surface of the base substrate in the direction perpendicular to the main surface of the base substrate. In some other embodiments, the overall pattern density in the region R2 may be substantially equal to the overall pattern density in the region R3, and the distance H2 between the flat surface S2 and the main surface of the base substrate 100 may also be substantially equal to the distance H3 between the flat surface S3 and the main surface of the base substrate 100. The distance between the flat surface and the main surface of the base substrate as described above is the distance in the direction perpendicular to the main surface of the base substrate 100.

In some embodiments, at least the portions of a plurality of light-emitting devices of the light-emitting device layer 116 arranged in the corresponding sub-pixel openings are located on the corresponding flat portions of the planarization layer. Since each flat portion of the planarization layer corresponding to each sub-pixel opening has a flat surface with high flatness, the light-emitting device in each sub-pixel light-emitting region of the light-emitting device layer 116 is arranged on the flat surface, so that the uniformity of light emission of various sub-pixels can be increased, and the display quality of the display panel can be improved.

Referring to FIG. 2A, in some embodiments, the light-emitting device layer 116 includes light-emitting devices LE of a plurality of sub-pixels SP, and includes a first electrode layer, a light-emitting layer and a second electrode layer, wherein the light-emitting layer is located between the first electrode layer and the second electrode layer; the light-emitting device LE of each sub-pixel SP may include a first electrode E1 located at the first electrode layer, a second electrode E2 located at the second electrode layer, and a light-emitting layer 113 located between the first electrode and the second electrode. The first electrode layer is arranged on the planarization layer 111, and the sub-pixel opening OP of the pixel defining layer 112 may expose at least part of the first electrode E1. The light-emitting layer 113 is disposed on a side of the first electrode E1 away from the base substrate, and may be arranged along the surface of the sub-pixel opening OP to cover a sidewall of the pixel defining layer 112 and a surface of the first electrode E1 exposed by the sub-pixel opening OP; the light-emitting layer 113 may further extend to cover part of the surface (or referred to as a top wall) of the pixel defining layer 112 at a side away from the base substrate 100. The second electrode layer is located on a side of the light-emitting layer 113 away from the first electrode layer, and may extend (e.g., continuously extend) along the surface of the light-emitting layer 113 and the surface of the pixel defining layer 112 at a side away from the base substrate 100.

In some embodiments, the first electrode layer and the second electrode layer may each include an appropriate electrode material such as a metal, a metal oxide, or the like, and the light-emitting layer may include an organic light-emitting material. The first electrode E1 and the second electrode E2 may be used as the anode and cathode of the light-emitting device LE, respectively. In some embodiments, the second electrode layer extends continuously across sub-pixel regions and serves as a common cathode for a plurality of sub-pixels.

In some embodiments, the first electrode E1 of the light-emitting device LE of each sub-pixel may be connected to the corresponding sub-pixel circuit PC through a via V1, for example, may be connected to the source/drain electrode (e.g., the source electrode S) of the thin film transistor T in the sub-pixel circuit PC. The via V1 may be located in a planarization layer 111 and extends through the planarization layer 111 to connect the first electrode E1 to the corresponding source/drain electrode. In some embodiments, the via V1 and the sub-pixel opening OP are offset in a direction parallel to the main surface of the base substrate 100; that is, the via V1 is not provided at the position directly below the sub-pixel opening OP as illustrated in the figure; the orthographic projection of the via V1 on the main surface of the base substrate 100 may be located outside the orthographic projection of the sub-pixel opening OP on the main surface of the base substrate 100, so that the via V1 can be prevented from affecting the flatness of the first electrode E1 in the light-emitting region LR, and that at least a portion of the first electrode E1 located in the light-emitting region LR has a flat surface at a side away from the base substrate 100; further, in this way, the light-emitting layer 113 and the second electrode E2 in the light-emitting region LR that are formed on the first electrode E1 also have high flatness, so as to avoid some problems caused by unevenness of the light-emitting devices in the light-emitting region LR, thereby improving the reliability of the light-emitting devices and improving the uniformity of light emission of various sub-pixels.

Referring to FIG. 2B, in some embodiments, the light-emitting device LE1 of the sub-pixel SP1 includes a first electrode E1a, a light-emitting layer 113a and a second electrode E2; the light-emitting device LE2 of the sub-pixel SP2 includes a first electrode E1b, a light-emitting layer 113b and a second electrode E2; the light-emitting device LE3 of the sub-pixel SP3 includes a first electrode E1c, a light-emitting layer 113c, and a third electrode E2. The first electrodes E1a-E1c of the light-emitting devices LE1 to LE3 are respectively connected to the corresponding sub-pixel circuits through via holes; and for the sake of simplicity of the drawing, the via holes through which the first electrodes of the light-emitting devices are connected to the sub-pixel circuits are not specifically shown in FIG. 2B.

A plurality of light-emitting devices LE1 to LE3 are respectively arranged on a plurality of flat portions 111a-111c of the planarization layer 111; since there is a step difference between the plurality of flat portions 111a-111c, there is also a step difference between the plurality of light-emitting devices LE1 to LE3. For example, the light-emitting devices LE1, LE2 and LE3 are respectively arranged on the flat surfaces S1, S2 and S3 of the flat portions 111a, 111b and 111c, and the first electrodes E1a, E1b and E1c of the light-emitting devices LE1, LE2 and LE3 are in direct contact with the flat surfaces S1, S2 and S3, respectively. In some embodiments, at least the portions of the first electrodes E1a, E1b and E1c exposed by the sub-pixel openings are located on the corresponding flat surfaces S1, S2 and S3, so as to ensure the flatness of the first electrode in each light-emitting region and the flatness of other components of the light-emitting device located above the first electrode, thereby improving the uniformity of light emission of each sub-pixel.

In some embodiments, the orthographic projections of at least the portions of the first electrodes E1a-E1c exposed by the corresponding sub-pixel openings OP1-OP3 on the base substrate 100 are located within the ranges of orthographic projections of the corresponding flat surfaces S1, S2 and S3 on the base substrate 100. In some embodiments, the orthographic projection of the entire electrode of each of one or more of the first electrodes E1a to E1c on the base substrate 100 may be located within the range of orthographic projection of the corresponding one of flat surfaces S1-S3 on the base substrate 100. In some embodiments, one or more first electrodes may also extend across a plurality of flat portions of the planarization layer 111, that is, may be in contact with a plurality of flat surfaces of the planarization layer at different level heights, but the portion of the first electrode exposed by the sub-pixel opening is located on only one flat surface. For example, in some embodiments, the sub-pixel circuit of some sub-pixels is not arranged in the region corresponding to the respective sub-pixel opening but is arranged in a region close to other sub-pixel openings; therefore, the first electrode in the light-emitting device of such a sub-pixel may need to extend by a long distance so as to be connected to the sub-pixel circuit thereof. However, the present disclosure is not limited thereto.

For example, the sub-pixel circuit pc3 of the sub-pixel SP3 is not arranged in the region R3 directly below the sub-pixel opening OP3 but is arranged in the region closer to other sub-pixel openings OP1 and OP2; in this case, at least a portion of the first electrode E1c exposed by the sub-pixel opening OP3 may be located on the flat surface S3 of the flat portion 111c, while other portions of the first electrode E1c may extend from the flat surface S3 of the flat portion 111c to the flat surfaces S2 and/or S1 of other flat portions 111b and/or 111a so as to be connected to the sub-pixel circuit pc3 close to other sub-pixel openings. However, the present disclosure is not limited thereto. In some other embodiments, the first electrode E1c may be located on the first flat portion 111c without crossing other flat portions, and the corresponding circuit pattern of the sub-pixel circuit pc3 may extend from a region close to other sub-pixel openings to a region directly below the first electrode E1c and may be connected to the first electrode E1c through a via.

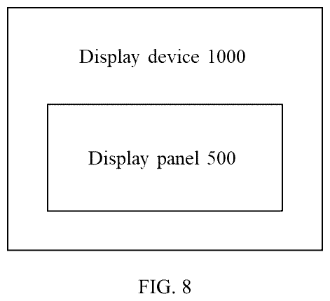

Referring to FIG. 8, in some embodiments, the present disclosure provides a display device 1000 including the display panel 500 of any of the above embodiments. By optimizing the arrangement of the pixel circuit layer in the display panel 500, the flatness of the region corresponding to each sub-pixel opening is improved, thereby improving the uniformity of light emission of the light-emitting device in each sub-pixel, and further improving the display quality of the display panel 500 and the display device 1000.

The embodiment of the present disclosure provides a method for forming a display panel, including: providing a base substrate; and forming a plurality of sub-pixels on the base substrate. Each sub-pixel includes a light-emitting device and a sub-pixel circuit for driving the light-emitting device to emit light, and the plurality of sub-pixels include a first sub-pixel, a second sub-pixel and a third sub-pixel for displaying different colors. Forming the plurality of sub-pixels includes: forming a pixel circuit layer, wherein the pixel circuit layer includes sub-pixel circuits of the plurality of sub-pixels and includes a first sub-pixel circuit, a second sub-pixel circuit and a third sub-pixel circuit for driving light-emitting devices of the first sub-pixel, the second sub-pixel and the third sub-pixel to emit light, respectively; forming a planarization layer on a side of the pixel circuit layer away from the base substrate; and forming a pixel defining layer on a side of the planarization layer away from the pixel circuit layer. The pixel defining layer has a plurality of sub-pixel openings, wherein each sub-pixel opening is configured to define a light-emitting region of a corresponding sub-pixel, and at least part of the light-emitting device of each sub-pixel is formed in a corresponding sub-pixel opening, wherein the plurality of sub-pixel openings include a first sub-pixel opening, a second sub-pixel opening and a third sub-pixel opening corresponding to the first sub-pixel, the second sub-pixel and the third sub-pixel, respectively. The pixel circuit layer includes a first conductive layer including a plurality of first circuit patterns of the plurality of sub-pixels, and the orthographic projection of the plurality of first circuit patterns on the base substrate overlaps with the orthographic projection of at least one of the first sub-pixel opening, the second sub-pixel opening and the third sub-pixel opening on the base substrate; the ratio of the overlapping area of the plurality of first circuit patterns with the third sub-pixel opening to the area of the third sub-pixel opening is smaller than the ratio of the overlapping area of the plurality of first circuit patterns with the first sub-pixel opening to the area of the first sub-pixel opening or the ratio of the overlapping area of the plurality of first circuit patterns with the second sub-pixel opening to the area of the second sub-pixel opening.

For example, in the method for forming the display panel described above, forming the pixel circuit layer includes: forming an active material layer on a side of the base substrate; forming the first conductive layer on a side of the active material layer away from the base substrate; and forming a second conductive layer on a side of the first conductive layer away from the base substrate; wherein each sub-pixel circuit includes a first circuit pattern located at the first conductive layer, a second circuit pattern located at the second conductive layer and an active pattern located at the active material layer.

For example, in the method for forming the display panel described above, forming the first conductive layer includes: arranging wires with substantially the same line width in a region corresponding to the same sub-pixel opening.

For example, in the method for forming the display panel described above, the second conductive layer includes a plurality of first wires and a plurality of second wires, wherein the plurality of first wires have substantially the same first line width, and the plurality of second wires have substantially the same second line width. Forming the second conductive layer includes: forming the plurality of first wires in a region corresponding to the first sub-pixel opening and forming the plurality of second wires in a region corresponding to the second sub-pixel opening.

For example, in the method for forming the display panel described above, forming the active material layer includes: forming all of the active patterns of the first sub-pixel circuit, the second sub-pixel circuit and the third sub-pixel circuit in a region corresponding to the first sub-pixel opening; or, forming the active patterns of both of the first sub-pixel circuit and the second sub-pixel circuit in the region corresponding to the first sub-pixel opening, and forming the active pattern of the third sub-pixel circuit in a region corresponding to the third sub-pixel opening.

For example, the method for forming the display panel described above, further includes at least one of the following steps: forming the first conductive layer further includes forming a first dummy pattern in a gap region of the first circuit patterns of the plurality of sub-pixels; forming the second conductive layer further includes forming a second dummy pattern in a gap region of the second circuit patterns of the plurality of sub-pixels; and forming the active material layer further includes forming a third dummy pattern in a gap region of the active patterns of the plurality of sub-pixels.

For example, in some embodiments, the present disclosure provides a method for forming a display panel, including the following steps: providing a base substrate 100; and forming a plurality of sub-pixels on the base substrate, wherein each sub-pixel includes a light-emitting device and a sub-pixel circuit for driving the light-emitting device to emit light, and the plurality of sub-pixels include a plurality of sub-pixels for displaying different colors. Forming the plurality of sub-pixels includes: forming a pixel circuit layer 110 on a side of the base substrate 100, wherein the pixel circuit layer 110 includes sub-pixel circuits of the plurality of sub-pixels; and forming a pixel defining layer 112 and a light-emitting device layer 116 on a side of the pixel circuit layer 110 away from the base substrate 100. For example, after forming the pixel circuit layer 110, forming a planarization layer 111 on a side of the pixel circuit layer 110 away from the base substrate 100; forming a first electrode layer on a side of the planarization layer 111 away from the pixel circuit layer 110; forming a pixel defining material layer on the planarization layer 110 to cover the first electrode layer, and patterning the pixel defining material layer to form the pixel defining layer 112 having a plurality of sub-pixel openings, wherein the plurality of sub-pixel openings of the pixel defining layer 112 expose at least parts of a plurality of first electrodes of the first electrode layer; and forming a light-emitting layer and a second electrode layer on the first electrode layer and the pixel defining layer, wherein at least parts of the light-emitting layer and the second electrode layer are filled in the sub-pixel openings, thereby forming a plurality of light-emitting devices.

In some embodiments, an encapsulation layer 118 may be formed on a side of the light-emitting device layer 116 away from the base substrate 100. The encapsulation layer 118 may include an organic insulating material, an inorganic insulating material, or a combination thereof. The encapsulation layer 118 can prevent water, oxygen and the like from entering the light-emitting device layer and affecting the light emission of the light-emitting devices. In some embodiments, the display panel may further include a touch structure layer formed on a side of the light-emitting device layer 116 away from the base substrate 100. For example, the touch structure layer may be located on a side of the encapsulation layer away from the base substrate to realize the touch function of the display panel. The touch structure may be any type of touch structure such as a self-capacitance touch structure or a mutual-capacitance touch structure. For example, the self-capacitance touch structure or the mutual-capacitance touch structure may include at least one conductive layer, but the specific type and structure of the touch structure are not limited in the embodiment of the present disclosure.

Referring to FIG. 2B, in some embodiments, forming the pixel circuit layer 110 may include the following steps: forming an active material layer 10 on a side of the base substrate 100; forming an insulating layer 102 to cover a sidewall of the active material layer L0 and the surface of the active material layer L0 at a side away from the base substrate 100; forming a conductive layer L1 on a side of the active material layer L0 and the insulating layer 102 away from the base substrate 100; forming an insulating layer 105 to cover a sidewall of the conductive layer L1 and the surface of the conductive layer L0 at a side away from the base substrate; and forming a conductive layer L2 on a side of the conductive layer L1 and the insulating layer 105 away from the base substrate 100. The active material layer L0, the conductive layer L1 and the conductive layer L2 respectively include active patterns 101, circuit patterns 103 and circuit patterns 108 of the plurality of sub-pixels.

In some embodiments, when forming each layer of the pixel circuit layer 110, the arrangement of pixel circuit patterns in each layer is optimized to improve the flatness of a region of the planarization layer 111 corresponding to each sub-pixel opening region. The arrangement and related features of the pixel circuit patterns of each layer of the pixel circuit layer 100 can refer to those described above with reference to FIGS. 2A to 7, and will not be repeated here.

Forming the conductive layer L1 and the conductive layer L2 may include arranging corresponding circuit patterns in region(s) corresponding to one or more sub-pixel openings. For example, forming the conductive layer L1 may include arranging wires having substantially the same line width in a region corresponding to the same one pixel opening (e.g., the sub-pixel opening OP1). In some embodiments, when a plurality of circuit patterns with different line widths are included in the conductive layer, the plurality of circuit patterns with different line widths may be classified, and the circuit patterns with close (e.g., substantially the same) line widths may be arranged in the region corresponding to the same one sub-pixel opening. For example, forming the second conductive layer may include forming a plurality of first wires in a region corresponding to a first sub-pixel opening (e.g., sub-pixel opening OP1) and forming a plurality of second wires in a region corresponding to a second sub-pixel opening (e.g., sub-pixel opening OP2). The plurality of first wires may have substantially the same first line width and first spacing; the plurality of second wires may have substantially the same second line width and second spacing, and the first line width may be different from the second line width, and the first spacing may be different from the second spacing.

In some embodiments, the method for forming a display panel according to the embodiment of the present disclosure may include at least one of the following steps: forming the conductive layer L1 further includes forming a first dummy pattern 103′ in the gap region of the circuit patterns 103; forming the conductive layer L2 further includes forming a second dummy pattern 108′ in the gap region of the circuit patterns 108; and forming the active material layer L0 further includes forming a third dummy pattern 101′ in the gap region of the active patterns 101. In some embodiments, the active patterns can be provided after optimizing the arrangement of each layer of the pixel circuit layer, including: concentratedly arranging the pixel circuit patterns of a plurality of sub-pixels in a region corresponding to a part of the sub-pixel openings, which may or may not include arranging these pixel circuit patterns to have equal line width and equal spacing. In the case where the pixel circuit patterns are not arranged to have equal line width and equal spacing, the density and uniformity of the overall arrangement of patterns in the region corresponding to the corresponding sub-pixel opening can be adjusted by adjusting the number, size and shape of the dummy patterns and the positional relationships between the dummy patterns and the pixel circuit patterns, thus improving the flatness of the planarization layer located above this region. In the case where the pixel circuit patterns (e.g., wire patterns) are arranged to have equal line width and equal spacing, the dummy pattern can be set to have substantially the same line width as the adjacent wire pattern, and the spacings between the dummy pattern and the adjacent wire patterns are set to be substantially the same, thereby improving the overall density and uniformity of the patterns in this region, and further improving the flatness of the planarization layer located above this region.

Specific features of the display panel formed by the method for forming the display panel according to the embodiment of the present disclosure can refer to those described above with respect to FIGS. 2A to 7, with the same technical effects as described above. According to the display panel and the method for forming the same disclosed by the present disclosure, the flatness of the planarization layer in the corresponding region is improved by optimizing the arrangement of the patterns in each layer of the pixel circuit layer, so that the planarization layer has a flat surface with high flatness at least in the region corresponding to each sub-pixel opening, and that at least a portion of the light-emitting device located in the light-emitting region is formed on the flat surface, thereby ensuring the uniformity of light emission of light-emitting device in each sub-pixel and improving the display quality of the display panel and the display device.

It should be understood that OLED devices are described in the foregoing, by way of example, to explain the concept of the present disclosure, and the concept of adjusting the regional flatness by optimizing the arrangement of patterns of the present disclosure can also be applied to other types of display devices and/or devices in other fields.

The following statements should be noted:
(1) The drawings of the present disclosure involve only the structure(s) in connection with the embodiment(s) of the present disclosure, and other structure(s) can be referred to common design(s).
(2) In case of no conflict, features in one embodiment or in different embodiments can be combined to obtain new embodiments.

What have been described above are only specific implementations of the present disclosure, the protection scope of the present disclosure is not limited thereto. Any modifications or substitutions easily occur to those skilled in the art within the technical scope of the present disclosure should be within the protection scope of the present disclosure. Therefore, the protection scope of the present disclosure should be based on the protection scope of the claims.

1. A display panel, comprising:
a base substrate;
a plurality of sub-pixels, disposed on the base substrate, wherein each sub-pixel comprises a light-emitting device and a sub-pixel circuit for driving the light-emitting device to emit light, and the plurality of sub-pixels comprise a first sub-pixel, a second sub-pixel and a third sub-pixel for displaying different colors;
a pixel circuit layer, comprising sub-pixel circuits of the plurality of sub-pixels and comprising a first sub-pixel circuit, a second sub-pixel circuit and a third sub-pixel circuit for respectively driving light-emitting devices of the first sub-pixel, the second sub-pixel and the third sub-pixel to emit light;
a planarization layer, disposed on a side of the pixel circuit layer away from the base substrate; and
a pixel defining layer, disposed on a side of the planarization layer away from the pixel circuit layer, wherein the pixel defining layer has a plurality of sub-pixel openings each configured to define a light-emitting region of a corresponding sub-pixel, and at least a part of the light-emitting device of each sub-pixel is located in a corresponding sub-pixel opening, wherein the plurality of sub-pixel openings comprise a first sub-pixel opening, a second sub-pixel opening and a third sub-pixel opening corresponding to the first sub-pixel, the second sub-pixel and the third sub-pixel, respectively;
wherein the pixel circuit layer comprises a first conductive layer comprising a plurality of first circuit patterns of the plurality of sub-pixels, and an orthographic projection of the plurality of first circuit patterns on the base substrate overlaps with an orthographic projection of at least one of the first sub-pixel opening, the second sub-pixel opening and the third sub-pixel opening on the base substrate; and
a ratio of an overlapping area of the plurality of first circuit patterns with the third sub-pixel opening to an area of the third sub-pixel opening is smaller than a ratio of an overlapping area of the plurality of first circuit patterns with the first sub-pixel opening to an area of the first sub-pixel opening or a ratio of an overlapping area of the plurality of first circuit patterns with the second sub-pixel opening to an area of the second sub-pixel opening.

2. The display panel according to claim 1, wherein an orthographic projection of at least a part of the third sub-pixel circuit on the base substrate is located outside an orthographic projection of the third sub-pixel opening on the base substrate, and overlaps with an orthographic projection of the first sub-pixel opening or the second sub-pixel opening on the base substrate.

3. The display panel according to claim 1, wherein
each sub-pixel circuit comprises one or more thin film transistor and one or more capacitor; each thin film transistor comprises a gate electrode, a source/drain electrode and an active layer; each capacitor comprises electrode plates opposite to each other;
the pixel circuit layer further comprises a plurality of wires connected to a plurality of thin film transistors and capacitors of the plurality of sub-pixel circuits, and the plurality of wires comprise at least one of a group consisting of a gate signal line, a data signal line, a common electrode line, a detection signal line, a power supply voltage line and an auxiliary connection line; and
the pixel circuit layer comprises a plurality of layers of circuit patterns, and the plurality of first circuit patterns of the first conductive layer comprise gate electrodes or source/drain electrodes of the plurality of thin film transistors, and further comprise at least one of a group consisting of the electrode plates of the capacitors and the plurality of wires.

4. The display panel according to claim 1, wherein
the pixel circuit layer comprises a plurality of pattern layers each comprising a plurality of patterns, and the first conductive layer is an uppermost pattern layer among the plurality of pattern layers which is closest to the light-emitting device in a direction perpendicular to a main surface of the base substrate, or the first conductive layer is located on a side, away from the light-emitting device, of the uppermost pattern layer among the plurality of pattern layers.

5. The display panel according to claim 1, wherein
the pixel circuit layer further comprises a second conductive layer and an active material layer, and each sub-pixel circuit comprises a first circuit pattern located at the first conductive layer, a second circuit pattern located at the second conductive layer and an active pattern located at the active material layer; and
the first conductive layer is a layer where a gate electrode of a thin film transistor of the sub-pixel circuit is located, the second conductive layer is a layer where a source/drain electrode of the thin film transistor of the sub-pixel circuit is located, and the active material layer is a layer where an active layer of the thin film transistor of the sub-pixel circuit is located.

6. The display panel according to claim 5, wherein a sum of an overlapping area of the plurality of first circuit patterns of the plurality of sub-pixels with the second sub-pixel opening and an overlapping area of the plurality of first circuit patterns of the plurality of sub-pixels with the third sub-pixel opening is smaller than an overlapping area of the plurality of first circuit patterns with the first sub-pixel opening.

7. (canceled)

8. The display panel according to claim 5, wherein
an orthographic projection of at least part of the first circuit patterns of at least two of the first sub-pixel circuit, the second sub-pixel circuit and the third sub-pixel circuit on the base substrate overlaps with an orthographic projection of the first sub-pixel opening on the base substrate; or
an orthographic projection of the first circuit pattern of the third sub-pixel on the base substrate is located outside an orthographic projection of the third sub-pixel opening on the base substrate; or
an orthographic projection of the first circuit pattern of the second sub-pixel on the base substrate is located outside an orthographic projection of the second sub-pixel opening on the base substrate; or
an orthographic projection of at least part of each of the first circuit pattern of the first sub-pixel, the first circuit pattern of the second sub-pixel and the first circuit pattern of the third sub-pixel on the base substrate overlaps with an orthographic projection of the first sub-pixel opening on the base substrate; or
an orthographic projection of the second circuit pattern of the third sub-pixel on the base substrate is located outside an orthographic projection of the third sub-pixel opening on the base substrate and overlaps with an orthographic projection of at least one of the first sub-pixel opening and the second sub-pixel opening on the base substrate.

9-13. (canceled)

14. The display panel according to claim 5, wherein an orthographic projection of a portion of the first conductive layer on the base substrate overlaps with an orthographic projection of the first sub-pixel opening on the base substrate, and the portion of the first conductive layer comprises a plurality of wires having substantially the same line width, and spacings between adjacent wires among the plurality of wires is substantially the same.

15. (canceled)

16. The display panel according to claim 5, wherein
the second conductive layer comprises a first portion and a second portion, and orthographic projections of the first portion and the second portion on the base substrate overlap with orthographic projections of the first sub-pixel opening and the second sub-pixel opening on the base substrate, respectively, and
the first portion comprises a plurality of first wires, wherein the plurality of first wires have substantially the same first line width, and adjacent first wires have substantially the same first spacing; and
the second portion comprises a plurality of second wires, wherein the plurality of second wires have substantially the same second line width, and adjacent second wires have substantially the same second spacing.

17. (canceled)

18. The display panel according to claim 5, wherein
an orthographic projection of at least one of the active pattern of the second sub-pixel circuit and the active pattern of the third sub-pixel circuit on the base substrate overlaps with an
orthographic projection of the first sub-pixel opening on the base substrate; or orthographic projections of the active pattern of the second sub-pixel circuit and the active pattern of the third sub-pixel circuit on the base substrate are both located outside orthographic projections of the second sub-pixel opening and the third sub-pixel opening on the base substrate; or
orthographic projections of the active patterns of the first sub-pixel circuit, the second sub-pixel circuit and the third sub-pixel circuit on the base substrate each overlap with an orthographic projection of the first sub-pixel opening on the base substrate; or
an orthographic projection of the active pattern of the second sub-pixel circuit on the base substrate is located outside an orthographic projection of the second sub-pixel opening on the base substrate, and orthographic projections of the active pattern of the second sub-pixel circuit and the active pattern of the first sub-pixel circuit on the base substrate both overlap with an orthographic projection of the first sub-pixel opening on the base substrate; or
an orthographic projection of the active pattern of the third sub-pixel circuit on the base substrate overlaps with an orthographic projection of the third sub-pixel opening on the base substrate, and the orthographic projection of the third sub-pixel opening on the base substrate is located within a range of an orthographic projection of the active pattern of the third sub-pixel circuit on the base substrate.

19-22. (canceled)

23. The display panel according to claim 5, wherein
at least one of the first conductive layer, the second conductive layer and the active material layer comprises a block pattern, and an orthographic projection of a part of the block pattern on the base substrate overlaps with an orthographic projection of a sub-pixel opening on the base substrate; and
the block pattern comprises a body portion and a plurality of strip portions, wherein a hollowed-out portion is arranged between the plurality of strip portions, and the plurality of strip portions are connected with each other through the body portion, wherein an orthographic projection of the body portion on the base substrate is located outside an orthographic projection of the sub-pixel opening, and an orthographic projection of at least part of the plurality of strip portions on the base substrate overlaps with the orthographic projection of the sub-pixel opening.

24. (canceled)

25. The display panel according to claim 5, further comprising at least one of following features:
the first conductive layer further comprises a first dummy pattern, which is arranged in a gap region of the first circuit patterns of the plurality of sub-pixels, and an orthographic projection of the first dummy pattern on the base substrate overlaps with an orthographic projection of at least one of the first sub-pixel opening, the second sub-pixel opening and the third sub-pixel opening on the base substrate;
the second conductive layer further comprises a second dummy pattern, which is arranged in a gap region of the second circuit patterns of the plurality of sub-pixels, and an orthographic projection of the second dummy pattern on the base substrate overlaps with an orthographic projection of at least one of the first sub-pixel opening, the second sub-pixel opening and the third sub-pixel opening on the base substrate; and
the active material layer further comprises a third dummy pattern, which is arranged in a gap region of the active patterns of the plurality of sub-pixels, and an orthographic projection of the third dummy pattern on the base substrate overlaps with an orthographic projection of at least one of the first sub-pixel opening, the second sub-pixel opening and the third sub-pixel opening on the base substrate.

26. (canceled)

27. The display panel according to claim 25, wherein the first circuit pattern comprises a wire pattern adjacent to the first dummy pattern, the first dummy pattern and the wire pattern have substantially the same width, and spacings between adjacent patterns among the first dummy patterns and the wire patterns are substantially the same; or
the second circuit pattern comprises a wire pattern adjacent to the second dummy pattern, the second dummy pattern and the wire pattern have substantially the same width, and spacings between adjacent patterns among the second dummy patterns and the wire patterns are substantially the same.

28-30. (canceled)

31. The display panel according to claim 1-any one of claims 1-28, wherein the planarization layer comprises a first flat portion, a second flat portion and a third flat portion, and orthographic projections of the first sub-pixel opening, the second sub-pixel opening and the third sub-pixel opening on the base substrate are respectively located within ranges of orthographic projections of the first flat portion, the second flat portion and the third flat portion on the base substrate,
wherein the first flat portion, the second flat portion and the third flat portion respectively have a first flat surface, a second flat surface and a third flat surface close to the light-emitting device, and at least two of the first flat surface, the second flat surface and the third flat surface are located at different level heights relative to a main surface of the base substrate.

32. (canceled)

33. (canceled)

34. A display panel comprising:
a base substrate;
a plurality of sub-pixels, disposed on the base substrate, wherein each sub-pixel comprises a light-emitting device and a sub-pixel circuit for driving the light-emitting device to emit light, and the plurality of sub-pixels comprise a first sub-pixel, a second sub-pixel and a third sub-pixel for displaying different colors;
a pixel circuit layer, comprising sub-pixel circuits of the plurality of sub-pixels, and comprising a first sub-pixel circuit, a second sub-pixel circuit and a third sub-pixel circuit for respectively driving light-emitting devices of the first sub-pixel, the second sub-pixel and the third sub-pixel to emit light;
a planarization layer, disposed on a side of the pixel circuit layer away from the base substrate; and
a pixel defining layer, disposed on a side of the planarization layer away from the pixel circuit layer, and having a plurality of sub-pixel openings, wherein each sub-pixel opening is configured to define a light-emitting region of a corresponding sub-pixel, and at least a part of the light-emitting device of each sub-pixel is located in a corresponding sub-pixel opening, wherein the plurality of sub-pixel openings comprise a first sub-pixel opening, a second sub-pixel opening and a third sub-pixel opening corresponding to the first sub-pixel, the second sub-pixel and the third sub-pixel, respectively;
wherein the pixel circuit layer comprises a plurality of pattern layers, a first pattern layer among the plurality of pattern layers comprises a plurality of first patterns of the plurality of sub-pixels, and orthographic projections of the plurality of first patterns on the base substrate overlap with an orthographic projection of at least one of the first sub-pixel opening, the second sub-pixel opening and the third sub-pixel opening on the base substrate; and
an overlapping area of the plurality of first patterns with the first sub-pixel opening is greater than an overlapping area of the plurality of first patterns with the second sub-pixel opening or an overlapping area of the plurality of first patterns with the third sub-pixel opening.

35. The display panel of claim 34, wherein an overlapping area of the plurality of first patterns with at least one of the second sub-pixel opening and the third sub-pixel opening is zero.

36. (canceled)

37. The display panel according to claim 34, wherein an area of the first sub-pixel opening is greater than an area of the second sub-pixel opening, and the area of the second sub-pixel opening is greater than an area of the third sub-pixel opening.

38. The display panel according to claim 37, wherein the plurality of pattern layers further comprise a second pattern layer located on a side of the first pattern layer close to or away from the light-emitting device, the second pattern layer comprises a plurality of second patterns of the plurality of sub-pixels, and an overlapping area of the plurality of second patterns with the first sub-pixel opening is greater than an overlapping area of the plurality of second patterns with the second sub-pixel opening or the third sub-pixel opening.

39. The display panel according to claim 38, wherein
the overlapping area of the plurality of second patterns with the second sub-pixel opening is zero; or
the overlapping area of the plurality of second patterns with the third sub-pixel opening is zero or equal to the area of the third sub-pixel opening.

40. (canceled)

41. (canceled)

42. A display device, comprising the display panel according to claim 1.
